(19) United States
(12) Patent Application Publication
(10) Pub. No.: US 2024/0260335 A1
(43) Pub. Date: Aug. 1, 2024

(54) DISPLAY APPARATUS AND METHOD OF MANUFACTURING THE SAME

(71) Applicant: Samsung Display Co., Ltd., Yongin-si (KR)

(72) Inventors: Yeongwoo Kwon, Yongin-si (KR); Jeongwon Kim, Yongin-si (KR); Junhong Park, Yongin-si (KR)

(73) Assignee: Samsung Display Co., Ltd., Yongin-si (KR)

(21) Appl. No.: 18/421,245

(22) Filed: Jan. 24, 2024

(30) Foreign Application Priority Data
Jan. 26, 2023 (KR) 10-2023-0010226

(51) Int. Cl. H10K 59/123; H10K 59/12; H10K 59/122; H10K 59/80; H10K 59/88; H10K 59/35

(52) U.S. Cl. CPC H10K 59/123; H10K 59/1201; H10K 59/122; H10K 59/8731; H10K 59/88; H10K 59/353

(57) ABSTRACT

A display apparatus includes a first sub-pixel electrode, a first structure surrounding the first sub-pixel electrode in a plan view, a first intermediate layer disposed on an inner surface of the first structure facing the first opening, the first intermediate layer overlapping the first sub-pixel electrode, a first portion of a first dummy intermediate layer disposed on the first structure, and a second portion of the first dummy intermediate layer disposed on an outer surface which is opposite to the inner surface of the first structure. The first intermediate layer, the first portion of the first dummy intermediate layer, and the second portion of the first dummy intermediate layer are apart from each other. The first intermediate layer, the first portion of the first dummy intermediate layer, and the second portion of the first dummy intermediate layer include a same material.

### CROSS-REFERENCE TO RELATED APPLICATION(S)

This application claims priority to and benefits of Korean Patent Application No. 10-2023-0010226 under 35 U.S.C. § 119, filed on Jan. 26, 2023 in the Korean Intellectual Property Office, the entire contents of which are incorporated herein by reference.

### BACKGROUND

### 1. Technical Field

One or more embodiments relate to a structure of a display apparatus and a method of manufacturing the display apparatus.

### 2. Description of the Related Art

A display apparatus visually displays data. The display apparatus may include a substrate divided into a display area and a peripheral area. A scan line is insulated from a data line in the display area, and sub-pixels may be arranged in the display area. A thin-film transistor and a pixel electrode electrically connected to the thin-film transistor may be mounted in the display area, wherein each of the thin-film transistor and the pixel electrode corresponds to each of the sub-pixels. In addition, an opposite electrode may be mounted in the display area in common for all of the sub-pixels. Various wirings, a scan driver, a data driver, a controller, a pad portion, and the like configured to transfer electrical signals to the display area may be mounted in the peripheral area.

The usage of display apparatuses has diversified. Accordingly, various attempts have been made to design a display apparatus with improved quality.

### SUMMARY

One or more embodiments include a display apparatus with improved resolution and capable of implementing excellent image quality. However, such a technical problem is an example, and the disclosure is not limited thereto.

Additional aspects will be set forth in part in the description which follows and, in part, will be apparent from the description, or may be learned by practice of the embodiments of the disclosure.

According to one or more embodiments, a display apparatus may include a first sub-pixel electrode, a first structure including a first opening and surrounding the first sub-pixel electrode in a plan view, the first opening overlapping the first sub-pixel electrode, an inorganic bank layer disposed on the first sub-pixel electrode and under the first structure, a first intermediate layer disposed on an inner surface of the first structure facing the first opening, the first intermediate layer overlapping the first sub-pixel electrode, a first opposite electrode disposed on an inner surface of the first structure facing the first opening, wherein the first opposite electrode overlaps the first intermediate layer, a first portion of a first dummy intermediate layer disposed on the first structure, and a second portion of the first dummy intermediate layer disposed on an outer surface which is opposite to the inner surface of the first structure. The first intermediate layer, the first portion of the first dummy intermediate layer, and the second portion of the first dummy intermediate layer may be apart from each other. The first intermediate layer, the first portion of the first dummy intermediate layer, and the second portion of the first dummy intermediate layer may include a same material.

The display apparatus may further include a substrate, a thin-film transistor disposed on the substrate, and an organic insulating layer disposed on the thin-film transistor, wherein the second portion of the first dummy intermediate layer may be disposed on the organic insulating layer.

The display apparatus may further include a first portion of a first dummy opposite electrode disposed on the first portion of the first dummy intermediate layer, and a second portion of the first dummy opposite electrode disposed on the second portion of the first dummy intermediate layer. The first opposite electrode, the first portion of the first dummy opposite electrode, and the second portion of the first dummy opposite electrode may be apart from each other. The first opposite electrode, the first portion of the first dummy opposite electrode, and the second portion of the first dummy opposite electrode may include a same material.

The display apparatus may further include a second sub-pixel electrode, a second structure including a second opening and surrounding the second sub-pixel electrode, the second opening overlapping the second sub-pixel electrode, a second intermediate layer disposed on an inner surface of the second structure facing the second opening, the second intermediate layer overlapping the second sub-pixel electrode, a second opposite electrode disposed on an inner surface of the second structure facing the second opening, the second opposite electrode overlapping the second intermediate layer, a first portion of a second dummy intermediate layer disposed on the second structure, and a second portion of the second dummy intermediate layer disposed on an outer surface which is opposite to the inner surface of the second structure. The second intermediate layer, the first portion of the second dummy intermediate layer, and the second portion of the second dummy intermediate layer may be apart from each other. The second intermediate layer, the first portion of the second dummy intermediate layer, and the second portion of the second dummy intermediate layer may include a same material.

The first structure and the second structure may be apart from each other.

The second portion of the first dummy intermediate layer and the second portion of the second dummy intermediate layer may be disposed between the first structure and the second structure.

The display apparatus may further include a first sub-pixel inorganic encapsulation layer disposed on the first opposite electrode, and a second sub-pixel inorganic encapsulation layer disposed on the second opposite electrode. The first sub-pixel inorganic encapsulation layer may extend to overlap an upper surface and a lateral surface of the first structure, and an upper surface of the first opposite electrode. The second sub-pixel inorganic encapsulation layer may extend to overlap an upper surface and a lateral surface of the second structure, and an upper surface of the second opposite electrode.

The first sub-pixel inorganic encapsulation layer and the second sub-pixel inorganic encapsulation layer may be apart from each other.

The first structure may include a separator, and two opposite sides of the separator may each be a reverse-tapered sloped surface.

The display apparatus may further include an auxiliary electrode disposed between the inorganic bank layer and the first structure, wherein the first opposite electrode may be in direct contact with the auxiliary electrode.

A width of the separator may be less than or equal to a width of the inorganic bank layer disposed under the separator.

A height of the separator may be about 2 μm to about 4 μm.

The separator may include at least one of an organic insulating material and a photosensitive material.

The first structure may include a metal bank layer, and the metal bank layer may include a first metal layer and a second metal layer on the first metal layer.

According to one or more embodiments, a method of manufacturing a display apparatus includes forming a first sub-pixel electrode, forming an inorganic bank layer covering an end of the first sub-pixel electrode, forming a first structure disposed on the inorganic bank layer, including a first opening, and surrounding the first sub-pixel electrode in a plan view, the first opening overlapping the first sub-pixel electrode, forming a first intermediate layer disposed on an inner surface of the first structure facing the first opening, the first intermediate layer overlapping the first sub-pixel electrode, forming a first opposite electrode disposed on the inner surface of the first structure facing the first opening, the first opposite electrode overlapping the first intermediate layer, forming a first portion of a first dummy intermediate layer disposed on the first structure, and forming a second portion of the first dummy intermediate layer disposed on an outer surface which is opposite to the inner surface of the first structure. The first intermediate layer and the first portion of the first dummy intermediate layer may be disconnected by the inner surface of the first structure. The first portion of the first dummy intermediate layer and the second portion of the first dummy intermediate layer may be disconnected by the outer surface of the first structure.

The method may further include forming a first portion of a first dummy opposite electrode disposed on the first portion of the first dummy intermediate layer, forming a second portion of the first dummy opposite electrode disposed on the second portion of the first dummy intermediate layer, and forming a first sub-pixel inorganic encapsulation layer disposed on the first opposite electrode. The first opposite electrode and the first portion of the first dummy opposite electrode may be disconnected by the inner surface of the first structure. The first portion of the first dummy opposite electrode and the second portion of the first dummy opposite electrode may be disconnected by the outer surface of the first structure. The first sub-pixel inorganic encapsulation layer may extend to overlap an upper surface and a lateral surface of the first structure and an upper surface of the first opposite electrode.

The method may further include forming a second sub-pixel electrode, forming a second structure including a second opening overlapping the second sub-pixel electrode, the second structure surrounding the second sub-pixel electrode in a plan view, forming a second intermediate layer disposed on an inner surface of the second structure facing the second opening, the second intermediate layer overlapping the second sub-pixel electrode, forming a second opposite electrode disposed on the inner surface of the second structure facing the second opening, the second opposite electrode overlapping the second intermediate layer, forming a first portion of a second dummy intermediate layer disposed on the second structure, and forming a second portion of the second dummy intermediate layer disposed on an outer surface which is opposite to the inner surface of the second structure. The second intermediate layer and the first portion of the second dummy intermediate layer may be disconnected by the inner surface of the second structure. The first portion of the second dummy intermediate layer and the second portion of the second dummy intermediate layer may be disconnected by the outer surface of the second structure.

The first structure and the second structure may be apart from each other.

The forming of the first structure may include forming a separator having two opposite sides each having a form of a reverse-tapered sloped surface. The forming of the separator may include exposing and developing a photosensitive material of the separator.

The forming of the first structure may include forming a metal bank layer. The metal bank layer may include a first metal layer and a second metal layer on the first metal layer.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic perspective view of a display apparatus according to an embodiment;

FIGS. 2A and 2B are schematic diagrams of equivalent circuits of a light-emitting diode corresponding to a sub-pixel of the display apparatus and a sub-pixel circuit connected to a relevant light-emitting diode according to an embodiment;

FIG. 3 is a schematic plan view of a portion of the display apparatus according to an embodiment;

FIG. 4 is a schematic cross-sectional view of the display apparatus according to an embodiment;

FIG. 5 is a cross-sectional view of a stack structure of a light-emitting diode according to an embodiment;

FIGS. 6A to 6P are schematic cross-sectional views showing states corresponding to a process of manufacturing a display apparatus according to an embodiment; and

FIG. 7 is a schematic cross-sectional view of a portion of the display apparatus according to another embodiment.

### DETAILED DESCRIPTION OF THE EMBODIMENTS

Reference will now be made in detail to embodiments, examples of which are illustrated in the accompanying drawings, wherein like reference numerals refer to like elements throughout. In this regard, the embodiments may have different forms and should not be construed as being limited to the descriptions set forth herein. Accordingly, the embodiments are merely described below, by referring to the figures, to explain aspects of the description.

As used herein, the term “and/or” includes any and all combinations of one or more of the associated listed items. For example, “A and/or B” may be understood to mean any combination including “A, B, or A and B.” The terms “and” and “or” may be used in the conjunctive or disjunctive sense and may be understood to be equivalent to “and/or.”

For the purposes of this disclosure, the phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

While such terms as “first” and “second” may be used to describe various elements, such elements must not be limited to the above terms. The above terms are used to distinguish one element from another.

The singular forms “a,” “an,” and “the” as used herein are intended to include the plural forms as well unless the context clearly indicates otherwise.

It will be understood that the terms “comprise,” “comprising,” “has,” “have,” “having,” “include,” and “including” as used herein specify the presence of stated features or elements but do not preclude the addition of one or more other features or elements.

It will be further understood that, when a layer, region, or element is referred to as being “on” another layer, region, or element, it can be directly or indirectly on the other layer, region, or element. That is, for example, intervening layers, regions, or elements may be present.

Sizes of elements in the drawings may be exaggerated or reduced for convenience of explanation. As an example, the size and thickness of each element shown in the drawings may be arbitrarily represented for convenience of description, and thus, the disclosure is not necessarily limited thereto.

In the case where a certain embodiment may be implemented differently, a specific process order may be performed in the order different from the described order. As an example, two processes successively described may be simultaneously performed substantially or performed in the opposite order.

It will be understood that when a layer, region, or element is referred to as being “connected” to another layer, region, or element, it may be “directly connected” to the other layer, region, or element or may be “indirectly connected” to the other layer, region, or element with an additional layer, region, or element located therebetween.

It will be understood that the terms “connected to” or “coupled to” may include a physical and/or electrical connection or coupling.

The term “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

“About” or “approximately” or “substantially” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

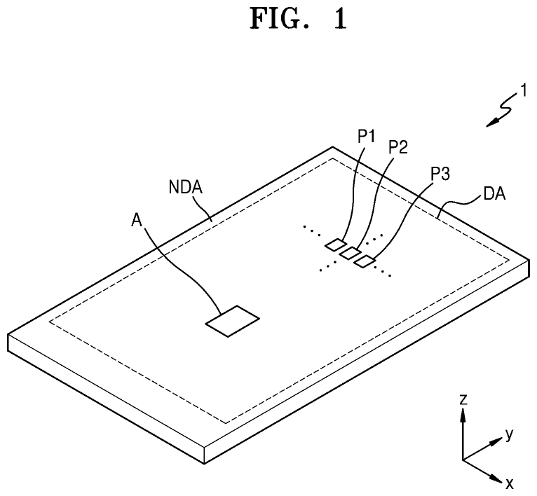

FIG. 1 is a schematic perspective view of a display apparatus 1 according to an embodiment.

Referring to FIG. 1, the display apparatus 1 may include a display area DA and a non-display area NDA outside the display area DA. The display area DA may be configured to display images through a first sub-pixel P1, a second sub-pixel P2, and a third sub-pixel P3 arranged (disposed) in the display area DA. The non-display area NDA may be arranged outside the display area DA and may not display images. The non-display area NDA may surround the display area DA entirely. A driver and the like configured to provide electrical signals or power to the display area DA may be arranged in the non-display area NDA. A pad may be arranged in the non-display area NDA. The pad may be a region to which electronic elements or a printed circuit board may be electrically connected.

In an embodiment, although FIG. 1 shows that the display area DA is a polygon (e.g., a quadrangle) in which a length thereof in an x direction is less than a length thereof in a y direction, the display area DA of the display apparatus 1 may be a polygon (e.g., a quadrangle) in which a length thereof in the y direction is less than a length thereof in the x direction in another embodiment. Although FIG. 1 shows the display area DA is approximately a quadrangle, the disclosure is not limited thereto. As another embodiment, the display area DA may have various shapes such as an N-gon (where N is a natural number of 3 or more), a circle, or an ellipse. Although it is shown in FIG. 1 that the display area DA has a shape in which a corner of the display area DA includes a vertex at which a straight line meets a straight line, the display area DA may have a polygon having round corners.

The display apparatus 1 is applicable to various products including televisions, notebook computers, monitors, advertisement boards, Internet of things (IoTs) as well as portable electronic apparatuses including mobile phones, smart phones, tablet personal computers (PCs), mobile communication terminals, electronic organizers, electronic books, portable multimedia players (PMPs), navigators, and ultra mobile personal computers (UMPCs). In addition, the display apparatus 1 according to an embodiment is applicable to wearable devices including smartwatches, watchphones, glasses-type displays, and head-mounted displays (HMDs). In addition, in an embodiment, the display apparatus 1 is applicable to a display screen in instrument panels for automobiles, center fascias for automobiles, or center information displays (CIDs) arranged on a dashboard, room mirror displays that replace side mirrors of automobiles, and displays of an entertainment system arranged on the backside of seats for backseat passengers in automobiles.

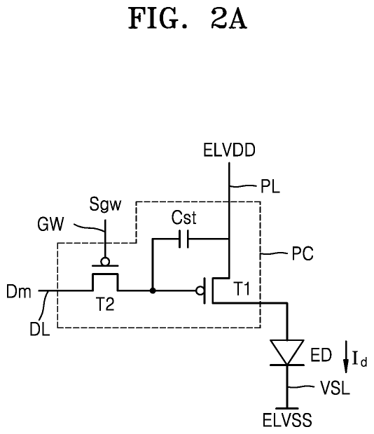

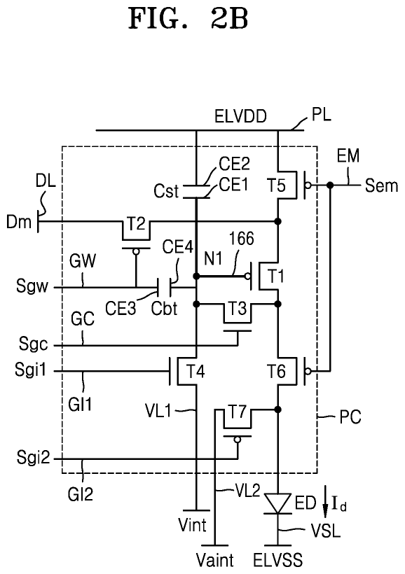

FIGS. 2A and 2B are schematic diagrams of equivalent circuits of a light-emitting diode corresponding to a sub-pixel of the display apparatus and a sub-pixel circuit electrically connected to a relevant light-emitting diode according to an embodiment.

Referring to FIG. 2A, a light-emitting diode ED may be electrically connected to a sub-pixel circuit PC, and the sub-pixel circuit PC may include a first transistor T1, a second transistor T2, and a storage capacitor Cst. A sub-pixel electrode (e.g., an anode) of the light-emitting diode ED may be electrically connected to the first transistor T1, and an opposite electrode (e.g., a cathode) may be electrically connected to an auxiliary line VSL and may receive a voltage corresponding to a common voltage ELVSS through the auxiliary line VSL.

The second transistor T2 may be configured to transfer a data signal Dm to the first transistor T1 according to a scan signal Sgw input through a scan line GW, wherein the data signal Dm is input through a data line DL.

The storage capacitor Cst may be connected to the second transistor T2 and a driving voltage line PL and configured to store a voltage corresponding to a difference between a voltage transferred from the second transistor T2 and a driving voltage ELVDD supplied to the driving voltage line PL.

The first transistor T1 may be connected to the driving voltage line PL and the storage capacitor Cst and configured to control a driving current I_{d} according to the voltage stored in the storage capacitor Cst, the driving current I_{d} flowing from the driving voltage line PL to the light-emitting diode ED. The light-emitting diode ED may be configured to emit light having a preset brightness corresponding to the driving current I_{d}.

Although it is described with reference to FIG. 2A that the sub-pixel circuit PC includes two transistors and one storage capacitor, the disclosure is not limited thereto.

Referring to FIG. 2B, the sub-pixel circuit PC may include seven transistors and two capacitors.

The sub-pixel circuit PC may include first to seventh transistors T1, T2, T3, T4, T5, T6, and T7, a storage capacitor Cst, and a boost capacitor Cbt. In another embodiment, the sub-pixel circuit PC may not include the boost capacitor Cbt. A sub-pixel electrode (e.g., an anode) of the light-emitting diode ED may be electrically connected to the first transistor T1 through the sixth transistor T6, and an opposite electrode (e.g., a cathode) may be electrically connected to the auxiliary line VSL and may receive a voltage corresponding to the common voltage ELVSS through the auxiliary line VSL.

Some of the transistors T1, T2, T3, T4, T5, T6, and T7 may be n-channel metal oxide semiconductor (NMOS) field-effect transistors (n-channel MOSFETs), and the rest may be p-channel metal oxide semiconductor (PMOS) field-effect transistors (p-channel MOSFETs). In an embodiment, as shown in FIG. 2B, the third and fourth transistors T3 and T4 may be n-channel MOSFETs, and the rest may be p-channel MOSFETs. As an example, the third and fourth transistors T3 and T4 may be n-channel MOSFETs including an oxide-based semiconductor material, and the rest may be p-channel MOSFETs including a silicon-based semiconductor material. In another embodiment, the third, fourth, and seventh transistors T3, T4, and T7 may be n-channel MOSFETs, and the rest may be p-channel MOSFETs.

The first to seventh transistors T1, T2, T3, T4, T5, T6, and T7, the storage capacitor Cst, and the boost capacitor Cbt may be connected to signal lines. The signal lines may include an emission control line EM, a compensation gate line GC, a first initialization gate line Gl1, a second initialization gate line Gl2, and the data line DL. The sub-pixel circuit PC may be electrically connected to a voltage line, for example, the driving voltage line PL, a first initialization voltage line VL1, and a second initialization voltage line VL2.

The first transistor T1 may be a driving transistor. A first gate electrode of the first transistor T1 may be connected to the storage capacitor Cst, a first electrode of the first transistor T1 may be electrically connected to the driving voltage line PL through the fifth transistor T5, and a second electrode of the first transistor T1 may be electrically connected to a first electrode (e.g., an anode) of the light-emitting diode ED through the sixth transistor T6. One of the first electrode and the second electrode of the first transistor T1 may be a source electrode, and the other may be a drain electrode. The first transistor T1 may be configured to supply the driving current I_{d} to the light-emitting diode ED according to a switching operation of the second transistor T2.

The second transistor T2 may be a switching transistor. A second gate electrode of the second transistor T2 may be connected to the scan line GW, a first electrode of the second transistor T2 may be connected to the data line DL, and a second electrode of the second transistor T2 may be connected to the driving first electrode of the first transistor T1 and electrically connected to the driving voltage line PL through the fifth transistor T5. One of the first electrode and the second electrode of the second transistor T2 may be a source electrode, and the other may be a drain electrode. The second transistor T2 may be turned on according to a scan signal Sgw transferred through the scan line GW and may perform a switching operation of transferring a data signal Dm to the first electrode of the first transistor T1, wherein the data signal Dm is transferred through the data line DL.

The third transistor T3 may be a compensation transistor configured to compensate for a threshold voltage of the first transistor T1. A third gate electrode of the third transistor T3 may be connected to a compensation gate line GC. A first electrode of the third transistor T3 may be connected to a lower electrode CE1 of the storage capacitor Cst through a node connection line 166, and connected to the first gate electrode of the first transistor T1. A first electrode of the third transistor T3 may be connected to the fourth transistor T4. A second electrode of the third transistor T3 may be connected to the second electrode of the first transistor T1 and electrically connected to the first electrode (e.g., the anode) of the light-emitting diode ED through the sixth transistor T6. One of the first electrode and the second electrode of the third transistor T3 may be a source electrode, and the other may be a drain electrode.

The third transistor T3 may be turned on according to a compensation signal Sgc transferred through the compensation gate line GC, and diode-connects the first transistor T1 by electrically connecting the first gate electrode to the second electrode (e.g., a drain electrode) of the first transistor T1.

The fourth transistor T4 may be a first initialization transistor configured to initialize the first gate electrode of the first transistor T1. A fourth gate electrode of the fourth transistor T4 may be connected to a first initialization gate line Gil. A first electrode of the fourth transistor T4 may be connected to the first initialization voltage line VL1. A second electrode of the fourth transistor T4 may be connected to the lower electrode CE1 of the storage capacitor Cst, the first electrode of the third transistor T3, and the first gate electrode of the first transistor T1. One of the first electrode and the second electrode of the fourth transistor T4 may be a source electrode, and the other may be a drain electrode. The fourth transistor T4 may be turned on according to a first initialization signal Sgi1 transferred through the first initialization gate line Gil and may perform an initialization operation of initializing the voltage of the first gate electrode of the first transistor T1 by transferring a first initialization voltage Vint to the first gate electrode of the driving transistor T1.

The fifth transistor T5 may be an operation control transistor. A fifth gate electrode of the fifth transistor T5 may be connected to the emission control line EM, a first electrode of the fifth transistor T5 may be connected to the driving voltage line PL, and a second electrode of the fifth transistor T5 may be connected to the first electrode of the first transistor T1 and the second electrode of the second transistor T2. One of the first electrode and the second electrode of the fifth transistor T5 may be a source electrode, and the other may be a drain electrode.

The sixth transistor T6 may be an emission control transistor. A sixth gate electrode of the sixth transistor T6 may be connected to the emission control line EM, a first electrode of the sixth transistor T6 may be connected to the second electrode of the first transistor T1 and the second electrode of the third transistor T3, and a second electrode of the sixth transistor T6 may be electrically connected to a second electrode of the seventh transistor T7 and the first electrode (e.g., the anode) of the light-emitting diode ED. One of the first electrode and the second electrode of the sixth transistor T6 may be a source electrode, and the other may be a drain electrode.

The fifth transistor T5 and the sixth transistor T6 may be simultaneously turned on according to an emission control signal Sem transferred through the emission control line EM, the driving voltage ELVDD may be transferred to the light-emitting diode ED, and the driving current I_{d} may flow through the light-emitting diode ED.

The seventh transistor T7 may be a second initialization transistor configured to initialize the first electrode of the light-emitting diode ED. A seventh gate electrode of the seventh transistor T7 may be connected to a second initialization gate line Gl2. A first electrode of the seventh transistor T7 may be connected to the second initialization voltage line VL2. A second electrode of the seventh transistor T7 may be connected to the second electrode of the sixth transistor T6 and the first electrode (e.g., the anode) of the light-emitting diode ED. The seventh transistor T7 may be turned on according to a second initialization signal Sgi2 transferred through the second initialization gate line Gl2, and configured to initialize the first electrode of the light-emitting diode ED by transferring a second initialization voltage Vaint to the first electrode (e.g., the anode) of the light-emitting diode ED.

In an embodiment, the second initialization voltage line VL2 may be a next scan line. As an example, the second initialization gate line Gl2 connected to the seventh transistor T7 of the sub-pixel circuit PC and arranged in an i-th row (i is a natural number), may correspond to a scan line of the sub-pixel circuit PC arranged in an (i+1)-th row. In another embodiment, the second initialization voltage line VL2 may be the emission control line EM. As an example, the emission control line EM may be electrically connected to the fifth to seventh transistors T5, T6, and T7.

The storage capacitor Cst may include the lower electrode CE1 and an upper electrode CE2. The lower electrode CE1 of the storage capacitor Cst may be connected to the first gate electrode of the first transistor T1, and the upper electrode CE2 of the storage capacitor Cst may be connected to the driving voltage line PL. The storage capacitor Cst may be configured to store charge corresponding to a difference between a voltage of the first gate electrode of the first transistor T1 and the driving voltage ELVDD.

The boost capacitor Cbt may include a third electrode CE3 and a fourth electrode CE4. The third electrode CE3 may be connected to the second gate electrode of the second transistor T2 and the scan line GW, and the fourth electrode CE4 may be connected to the first electrode of the third transistor T3 and the node connection line 166. The boost capacitor Cbt may raise the voltage of a first node N1 in case that a scan signal Sgw supplied to the scan line GW is a turn-off voltage. In case that the voltage of the first node N1 is raised, a black grayscale may be clearly expressed.

The first node N1 may be a region where the first gate electrode of the first transistor T1, the first electrode of the third transistor T3, the second electrode of the fourth transistor T4, and the fourth electrode CE4 of the boost capacitor Cbt are connected to each other.

In an embodiment, it is described in FIG. 2B that the third and fourth transistors T3 and T4 are n-channel MOSFETs, and the first, second, fifth to seventh transistors T1, T2, T5, T6, and T7 are p-channel MOSFETs. The first transistor T1 directly influencing the brightness of the display apparatus displaying images may be configured to include a semiconductor layer including polycrystalline silicon having high reliability, and thus, a high-resolution display apparatus may be implemented through this configuration.

Although it is described in FIG. 2B that some of the transistors are NMOSFETs and the rest are PMOSFETs, the disclosure is not limited thereto. In another embodiment, the sub-pixel circuit PC includes three transistors and all of the three transistors may be NMOSFETs. However, various modifications may be made.

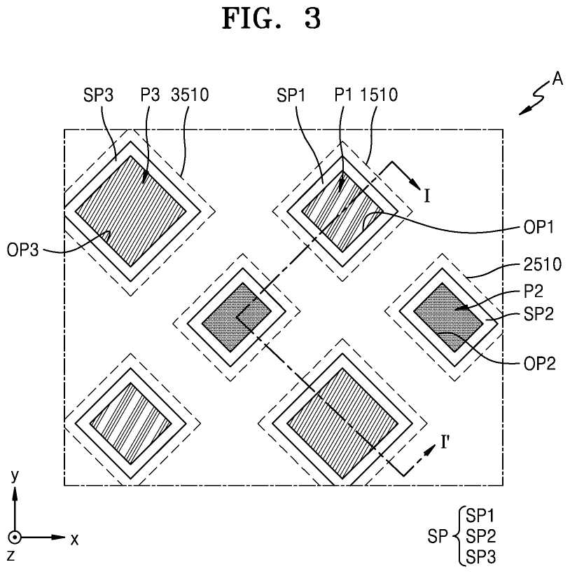

FIG. 3 is a schematic plan view of a portion of the display apparatus according to an embodiment. Specifically, FIG. 3 is an enlarged schematic plan view of a region A of FIG. 1.

Referring to FIG. 3, the display apparatus 1 may include sub-pixels. The sub-pixels may include a first sub-pixel P1, a second sub-pixel P2, and a third sub-pixel P3. The first sub-pixel P1, the second sub-pixel P2, and the third sub-pixel P3 may be sub-pixels configured to emit light of different colors. As an example, the first sub-pixel P1 may be a pixel configured to emit red light, the second sub-pixel P2 may be a pixel configured to emit blue light, and the third sub-pixel P3 may be a pixel configured to emit green light. Red light may be light in a wavelength band of about 580 nm to about 780 nm, blue light may be light in a wavelength band of about 400 nm to about 495 nm, and green light may be light in a wavelength band of about 495 nm to about 580 nm.

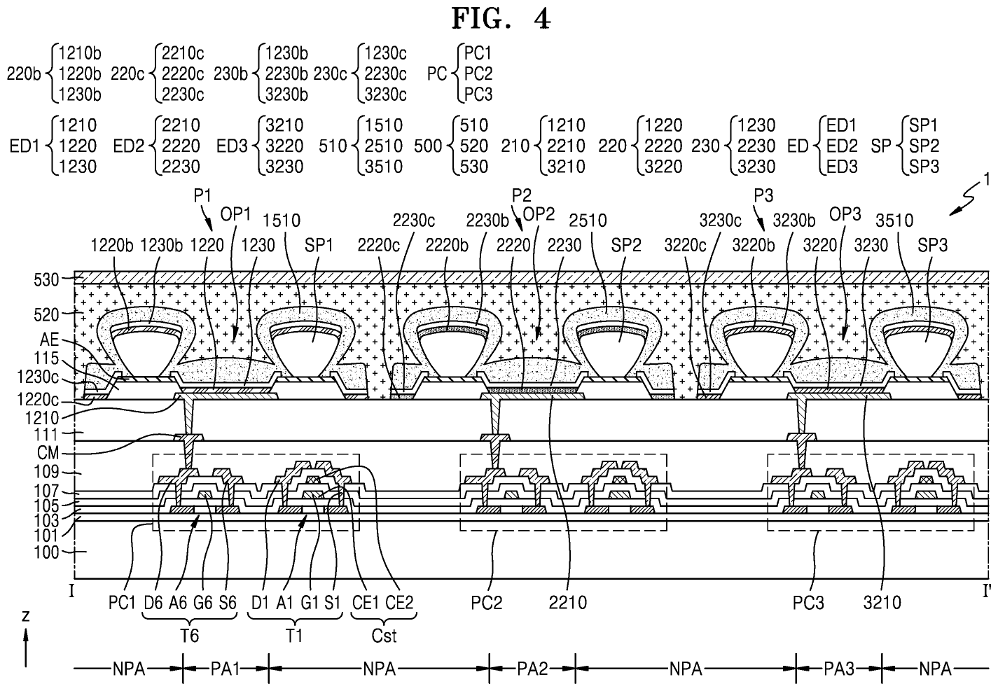

Each of the sub-pixels may include an organic light-emitting diode, and the organic light-emitting diode may include a sub-pixel electrode, an opposite electrode, and an intermediate layer therebetween. Accordingly, the first sub-pixel P1 may include a first sub-pixel electrode 1210 (see FIG. 4), the second sub-pixel P2 may include a second sub-pixel electrode 2210 (see FIG. 4), and the third sub-pixel P3 may include a third sub-pixel electrode 3210 (see FIG. 4). The first sub-pixel electrode 1210, the second sub-pixel electrode 2210, and the third sub-pixel electrode 3210 may be apart from each other in a plan view. In the present specification, “in a plan view” may mean viewed from a direction perpendicular to a substrate 100 (see FIG. 4). For example, “A and B apart from each other in a plan view” means “A and B apart from each other when viewed in a direction perpendicular to the substrate 100.”

The first sub-pixel P1 and the third sub-pixel P3 may be alternately arranged in a first row in a first direction (e.g., an x direction) in a plan view. The second sub-pixel P2 may be repeatedly arranged in a second row in the first direction (e.g., the x direction). The first row and the second row may be arbitrarily determined rows, and the first row and the second row may be alternately arranged in a second direction (e.g., a y direction) perpendicular to the first direction. The second sub-pixel P2 arranged in the second row may be arranged between the first sub-pixel P1 and the third sub-pixel P3 around the first direction (e.g., the x direction).

A separator SP (or a structure) may be arranged to surround each of the sub-pixels. The separator SP may include a first separator SP1, a second separator SP2, and a third separator SP3, wherein the first separator SP1 surrounds the first sub-pixel P1, the second separator SP2 surrounds the second sub-pixel P2, and the third separator SP3 surrounds the third sub-pixel P3. For example, the first separator SP1, the second separator SP2, and the third separator SP3 may respectively surround the first sub-pixel electrode 1210, the second sub-pixel electrode 2210, and the third sub-pixel electrode 3210. Specifically, the first separator SP1, the second separator SP2, and the third separator SP3 may be disposed on an inorganic bank layer 115 (see FIG. 4) covering an end of each of the first sub-pixel electrode 1210, the second sub-pixel electrode 2210, and the third sub-pixel electrode 3210.

Accordingly, the first separator SP1 may include a first opening OP1 exposing the central portion of the first sub-pixel electrode 1210, the second separator SP2 may include a second opening OP2 exposing the central portion of the second sub-pixel electrode 2210, and the third separator SP3 may include a third opening OP3 exposing the central portion of the third sub-pixel electrode 3210. Although not shown in FIG. 3, emission layers configured to emit light may be respectively arranged inside the first opening OP1, the second opening OP2, and the third opening OP3, and opposite electrodes may be respectively disposed on the emission layers. As described above, a stack structure of the sub-pixel electrode, the emission layer, and the opposite electrode may form an organic light-emitting diode. For example, an opening of the separator SP may correspond to an organic light-emitting diode and define an emission area. Each of the first opening OP1, the second opening OP2, and the third opening OP3 may have a polygonal shape when viewed in a direction (e.g., a z axis direction) perpendicular to the substrate 100. Although each of the first opening OP1, the second opening OP2, and the third opening OP3 has a quadrangular shape in a plan view, the disclosure is not limited thereto. As an example, each of the first opening OP1, the second opening OP2, and the third opening OP3 may have a circular shape or an elliptical shape in a plan view.

A first sub-pixel inorganic encapsulation layer 1510, a second sub-pixel inorganic encapsulation layer 2510, and a third sub-pixel inorganic encapsulation layer 3510 may be respectively disposed on the first sub-pixel P1, the second sub-pixel P2, and the third sub-pixel P3. For example, the first sub-pixel inorganic encapsulation layer 1510 may cover the first sub-pixel P1, the second sub-pixel inorganic encapsulation layer 2510 may cover the second sub-pixel P2, and the third sub-pixel inorganic encapsulation layer 3510 may cover the first sub-pixel P3. Specifically, the first sub-pixel inorganic encapsulation layer 1510, the second sub-pixel inorganic encapsulation layer 2510, and the third sub-pixel inorganic encapsulation layer 3510 may respectively cover partial regions beyond the first separator SP1, the second separator SP2, and the third separator SP3. The first sub-pixel inorganic encapsulation layer 1510, the second sub-pixel inorganic encapsulation layer 2510, and the third sub-pixel inorganic encapsulation layer 3510 may be apart from each other. Accordingly, the first sub-pixel inorganic encapsulation layer 1510, the second sub-pixel inorganic encapsulation layer 2510, and the third sub-pixel inorganic encapsulation layer 3510 may form a structure in which sealing is made on a sub-pixel basis.

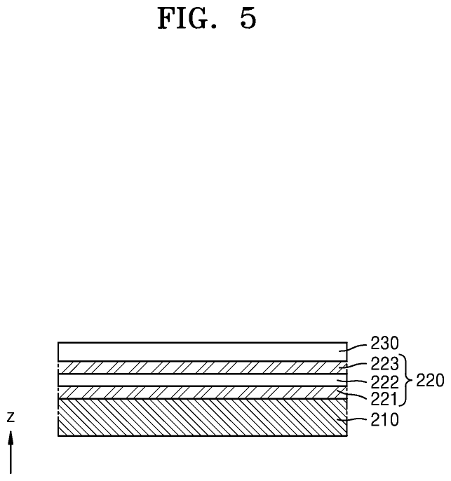

FIG. 4 is a schematic cross-sectional view of the display apparatus 1 according to an embodiment, and FIG. 5 is a cross-sectional view of a stack structure of a light-emitting diode according to an embodiment.

Referring to FIG. 4, the display apparatus 1 may include first to third sub-pixel areas PA1, PA2, and PA3 and include a non-sub-pixel area NPA between the adjacent sub-pixel areas. The planar shape of the display apparatus 1 may be actually the same as a planar shape of the substrate 100. Accordingly, in case that the display apparatus 1 includes the first to third sub-pixel areas PA1, PA2, and PA3 and the non-sub-pixel area NPA, it may represent that the substrate 100 includes the first to third sub-pixel areas PA1, PA2, and PA3 and the non-sub-pixel area NPA.

First, the sub-pixel circuit PC may be formed on the substrate 100. The sub-pixel circuit PC may include a first sub-pixel circuit PC1 of the first sub-pixel P1, a second sub-pixel circuit PC2 of the second sub-pixel P2, and a third sub-pixel circuit PC3 of the third sub-pixel P3. The first sub-pixel circuit PC1, the second sub-pixel circuit PC2, and the third sub-pixel circuit PC3 may include the same structure. The first to third sub-pixel circuits PC1, PC2, and PC3 may each include the transistor and the storage capacitor described above with reference to FIGS. 2A and 2B. In an embodiment, FIG. 4 shows the first transistor T1, the sixth transistor T6, and the storage capacitor Cst of each of the first to third sub-pixel circuits PC1, PC2, and PC3.

The substrate 100 may include glass or polymer resin. The substrate 100 may have a structure in which a base layer including polymer resin and an inorganic barrier layer are stacked on each other. The polymer resin may include polyethersulphone (PES), polyacrylate (PAR), polyetherimide (PEI), polyethylene naphthalate (PEN), polyethylene terephthalate (PET), polyphenylene sulfide (PPS), polyarylate, polyimide (PI), polycarbonate, cellulose tri acetate (TAC), cellulose acetate propionate (CAP), and/or the like.

A buffer layer 101 may be disposed on the upper surface of the substrate 100. The buffer layer 101 may prevent impurities from penetrating a semiconductor layer of a transistor. The buffer layer 101 may include an inorganic insulating material such as silicon nitride, silicon oxynitride, and silicon oxide, and include a single layer or a multi-layer including the above inorganic insulating materials.

The first transistor T1 may include a first semiconductor layer A1 and a first gate electrode G1, wherein the first semiconductor layer A1 is on the buffer layer 101, and the first gate electrode G1 overlaps a channel region of the first semiconductor layer A1. The first semiconductor layer A1 may include a silicon-based semiconductor material, for example, polycrystalline silicon. The first semiconductor layer A1 may include a channel region, a first region, and a second region, the first region and the second region being on two opposite sides of the channel region. The first region and the second region may be regions including impurities of higher concentration than that of the channel region. One of the first region and the second region may correspond to a source region, and the other may correspond to a drain region.

The sixth transistor T6 may include a sixth semiconductor layer A6 and a sixth gate electrode G6, wherein the sixth semiconductor layer A6 is on the buffer layer 101, and the sixth gate electrode G6 overlaps a channel region of the sixth semiconductor layer A6. The sixth semiconductor layer A6 may include a silicon-based semiconductor material, for example, polycrystalline silicon. The sixth semiconductor layer A6 may include a channel region, a first region, and a second region, the first region and the second region being on two opposite sides of the channel region. The first region and the second region may be regions including impurities of higher concentration than that of the channel region. One of the first region and the second region may correspond to a source region, and the other may correspond to a drain region.

The first gate electrode G1 and the sixth gate electrode G6 may include a conductive material including molybdenum (Mo), aluminum (Al), copper (Cu), and/or titanium (Ti) and have a single-layered structure or a multi-layered structure including the above materials. A first gate insulating layer 103 may be disposed below the first gate electrode G1 and the sixth gate electrode G6, wherein the first gate insulating layer 103 is for electrical insulation between the first semiconductor layer A1 and the first gate electrode G1 and between the sixth semiconductor layer A6 and the sixth gate electrode G6. The first gate insulating layer 103 may include an inorganic insulating material such as silicon nitride, silicon oxynitride, and/or silicon oxide, and include a single layer or a multi-layer including the above inorganic insulating materials.

The storage capacitor Cst may include the lower electrode CE1 and the upper electrode CE2 overlapping each other. In an embodiment, the lower electrode CE1 of the storage capacitor Cst may include the first gate electrode G1. In other words, the first gate electrode G1 may include the lower electrode CE1 of the storage capacitor Cst. As an example, the first gate electrode G1 and the lower electrode CE1 of the storage capacitor Cst may be one body.

A first interlayer insulating layer 105 may be disposed between the lower electrode CE1 and the upper electrode CE2 of the storage capacitor Cst. The first interlayer insulating layer 105 may include an inorganic insulating material such as silicon nitride, silicon oxynitride, and/or silicon oxide, and include a single-layered structure or a multi-layered structure including the above inorganic insulating materials.

The upper electrode CE2 of the storage capacitor Cst may include a conductive material of a low-resistance material such as molybdenum (Mo), aluminum (Al), copper (Cu) and/or titanium (Ti), and have a single-layered structure or a multi-layered structure including the above materials.

A second interlayer insulating layer 107 may be disposed between the upper electrode CE2 of the storage capacitor Cst and a source electrode S1 and/or a drain electrode D1. The second interlayer insulating layer 107 may include an inorganic insulating material such as silicon nitride, silicon oxynitride, and/or silicon oxide, and include a single-layered structure or a multi-layered structure including the above inorganic insulating materials.

The source electrode S1 and/or the drain electrode D1 may be disposed on the second interlayer insulating layer 107, the source electrode S1 and/or the drain electrode D1 being electrically connected to the first semiconductor layer A1 of the first transistor T1. A source electrode S6 and/or a drain electrode D6 may be disposed on the second interlayer insulating layer 107, the source electrode S6 and/or the drain electrode D6 being electrically connected to the sixth semiconductor layer A6 of the sixth transistor T6. The source electrodes S1 and S6 and/or the drain electrodes D1 and D6 may include aluminum (Al), copper (Cu), and/or titanium (Ti), and include a single layer or a multi-layer structure including the above materials.

A first organic insulating layer 109 may be disposed on the sub-pixel circuit PC. The first organic insulating layer 109 may include an organic insulating material such as acryl, benzocyclobutene (BCB), polyimide, and/or hexamethyldisiloxane (HMDSO).

A connection metal CM may be disposed on the first organic insulating layer 109. The connection metal CM may include aluminum (Al), copper (Cu), and/or titanium (Ti), and include a single layer or a multi-layer including the above materials.

A second organic insulating layer 111 may be disposed between the connection metal CM and the sub-pixel electrode 210. The second organic insulating layer 111 may include an organic insulating material such as acryl, benzocyclobutene (BCB), polyimide, or hexamethyldisiloxane (HMDSO). According to an embodiment described with reference to FIG. 4, although the sub-pixel circuit PC is electrically connected to the sub-pixel electrode 210 through the connection metal CM, the connection metal CM may be omitted and one organic insulating layer may be located between the sub-pixel circuit PC and the sub-pixel electrode 210 according to another embodiment. Three or more organic insulating layers may be located between the sub-pixel circuit PC and the sub-pixel electrode 210, and the sub-pixel circuit PC may be electrically connected to the sub-pixel electrode 210 through connection metals.

The first to third light-emitting diodes ED1, ED2, and ED3 respectively electrically connected to the first to third sub-pixel circuits PC1, PC2, and PC3 may each have a stack structure of the sub-pixel electrode 210, an intermediate layer 220, and an opposite electrode 230.

As an example, the first light-emitting diode ED1 may include a first sub-pixel electrode 1210, a first intermediate layer 1220, and a first opposite electrode 1230. The first sub-pixel electrode 1210 may be electrically connected to the first sub-pixel circuit PC1. The second light-emitting diode ED2 may include a second sub-pixel electrode 2210, a second intermediate layer 2220, and a second opposite electrode 2230. The second sub-pixel electrode 2210 may be electrically connected to the second sub-pixel circuit PC2. The third light-emitting diode ED3 may include a third sub-pixel electrode 3210, a third intermediate layer 3220, and a third opposite electrode 3230. The third sub-pixel electrode 3210 may be electrically connected to the third sub-pixel circuit PC3.

The sub-pixel electrode 210 may be formed on the second organic insulating layer 111. The sub-pixel electrode 210 may be formed to be a (semi) transparent electrode or formed to be a reflective electrode. In the case where the sub-pixel electrode 210 includes a (semi) transparent electrode, the sub-pixel electrode 210 may include indium tin oxide (ITO), indium zinc oxide (IZO), zinc oxide (ZnO), indium oxide (In₂O₃), indium gallium oxide (IGO), and/or aluminum zinc oxide (AZO). In the case where the sub-pixel electrode 210 includes a reflective electrode, the sub-pixel electrode 210 may include a reflective layer including Ag, Mg, Al, Pt, Pd, Au, Ni, Nd, Ir, Cr, and/or a compound thereof, and a layer on the reflective layer, the layer including ITO, IZO, ZnO and/or In₂O₃. In an embodiment, the sub-pixel electrode 210 may have a structure of an ITO layer, an Ag layer, and an ITO layer that are sequentially stacked on each other. The sub-pixel electrode 210 may be electrically connected to the connection metal CM through a contact hole of the second organic insulating layer 111.

The first sub-pixel electrode 1210, the second sub-pixel electrode 2210, and the third sub-pixel electrode 3210 may each include an inner portion and an outer portion surrounding the inner portion. In the specification, an “outer portion (or neighboring portion)” of the sub-pixel electrode denotes a portion of the sub-pixel electrode including the edge of the sub-pixel electrode, and an “inner portion of the sub-pixel electrode” denotes another portion of the sub-pixel area surrounded by the outer portion (or neighboring portion).

The inorganic bank layer 115 may be formed on the sub-pixel electrode 210. The inorganic bank layer 115 may be disposed on the sub-pixel electrode 210 to cover an outer portion of the sub-pixel electrode 210. As an example, the inorganic bank layer 115 may overlap the sub-pixel electrode 210 and be in direct contact with the upper surface of the second organic insulating layer 111 where the sub-pixel electrode 210 is not present. The inorganic bank layer 115 may cover the lateral surface of each of the sub-pixel electrode 210. The inorganic bank layer 115 may include an inorganic insulating material. In the case where the inorganic bank layer 115 includes an inorganic insulating material, the quality of the light-emitting diode may be prevented or reduced from being deteriorated by a gas emitted from an insulating layer, which is an organic insulating material, during the process of manufacturing the display apparatus compared to the case where the inorganic bank layer 115 includes an organic insulating material.

The inorganic bank layer 115 may include an inorganic insulating material such as silicon nitride, silicon oxynitride, and silicon oxide, and include a single-layered structure or a multi-layered structure including the above inorganic insulating materials. In an embodiment, the inorganic bank layer 115 may have a two-layered structure of a silicon oxide layer and a silicon nitride layer. The thickness of the silicon oxide layer may be less than the thickness of the silicon nitride layer.

The inorganic bank layer 115 may be arranged to surround the first sub-pixel P1, the second sub-pixel P2, and the third sub-pixel P3. Specifically, the inorganic bank layer 115 may surround the first sub-pixel electrode 1210 while including an opening exposing the central portion of the first sub-pixel electrode 1210. The opening of the inorganic bank layer 115 may overlap the first opening OP1 of the first separator SP1 described below. Likewise, the inorganic bank layer 115 may include openings respectively exposing the central portions of the second sub-pixel electrode 2210 and the third sub-pixel electrode 3210. The openings of the inorganic bank layer 115 may respectively overlap the second opening OP2 of the second separator SP2 and the third opening OP3 of the third separator SP3 described below.

As in FIG. 4, a portion of the inorganic bank layer 115 in the non-sub-pixel area NPA between the first sub-pixel P1 and the second sub-pixel P2 may be removed. Likewise, a portion of the inorganic bank layer 115 in the non-sub-pixel area NPA between the second sub-pixel P2 and the third sub-pixel P3 may be removed. For example, a portion of the inorganic bank layer 115 between respective pixels may be removed and separated. Accordingly, because a step difference is formed in the inorganic bank layer 115 partially removed from the non-sub-pixel area NPA, penetration of moisture and contaminants from the outside into the sub-pixel may be more effectively prevented. However, the disclosure is not limited thereto and the inorganic bank layer 115 may extend without a step difference in a region in which an auxiliary electrode AE is connected between adjacent sub-pixels.

The auxiliary electrode AE may be disposed on the inorganic bank layer 115. The auxiliary electrode AE may be an electrode connected to the auxiliary line VSL (see FIG. 2A) described above. The auxiliary electrode AE may be configured to receive a voltage corresponding to the common voltage ELVSS through the auxiliary line VSL. Accordingly, the auxiliary electrode AE may include a conductive material. The auxiliary electrode AE may include the same material as a material of the source electrode S1 or the drain electrode D1 of the sub-pixel circuit PC described above. In another embodiment, the auxiliary electrode AE may include the same material as a material of the connection metal CM. As an example, the auxiliary electrode AE may include aluminum (Al), copper (Cu), and/or titanium (Ti), and include a single layer or a multi-layer including the above materials.

The auxiliary electrode AE may be arranged to overlap the inorganic bank layer 115 and surround the first to third sub-pixel electrodes 1210, 2210, and 3210. The auxiliary electrode AE may be arranged to surround each of the first light-emitting diode ED1, the second light-emitting diode ED2, the third light-emitting diode ED3, and like the inorganic bank layer 115, be partially removed between adjacent light-emitting diodes. Although not shown in FIG. 4, the auxiliary electrode AE may further include a portion connected between adjacent light-emitting diodes. For example, the auxiliary electrode AE may further include a partial region connecting respective sub-pixels while surrounding the first sub-pixel P1, the second sub-pixel P2, and the third sub-pixel P3 in a plan view of the auxiliary electrode AE.

The separator SP (or a structure) may be disposed on the auxiliary electrode AE. The separator SP may be arranged to overlap the auxiliary electrode AE and the inorganic bank layer 115 and surround the first to third sub-pixel electrodes 1210, 2210, and 3210 in a plan view. Specifically, the separator SP may include the first separator SP1, the second separator SP2, and the third separator SP3, wherein the first separator SP1 may surround the first sub-pixel electrode 1210 in a plan view, the second separator SP2 may surround the second sub-pixel electrode 2210 in a plan view, and the third separator SP3 may surround the third sub-pixel electrode 3210 in a plan view. The first separator SP1, the second separator SP2, and the third separator SP3 may be apart from each other. For example, the separator SP may have an isolated island shape in a plan view.

Because the separator SP is arranged to surround each sub-pixel electrode 210, each separator SP may include one opening. As an example, the first separator SP1 may include the first opening OP1 overlapping the first sub-pixel electrode 1210, the second separator SP2 may include the second opening OP2 overlapping the second sub-pixel electrode 2210, and the third separator SP3 may include the third opening OP3 overlapping the third sub-pixel electrode 3210. Specifically, the first separator SP1 surrounding the first sub-pixel P1 may include the first opening OP1 and expose the central portion of the first sub-pixel electrode 1210. Likewise, the second separator SP2 surrounding the second sub-pixel P2 may include the second opening OP2 and expose the central portion of the second sub-pixel electrode 2210, and the third separator SP3 surrounding the third sub-pixel P3 may include the third opening OP3 and expose the central portion of the third sub-pixel electrode 3210. For example, the separator SP may have a ring shape surrounding each sub-pixel in a plan view.

The separator SP may have a reversed-tapered shape in cross-section. Specifically, the separator SP may have a shape in which a width of an upper surface thereof is greater than a width of a bottom surface thereof. A lateral surface of the separator SP connecting the upper surface of the separator SP to the bottom surface may include a sloped surface. For example, two opposite surfaces of the separator SP may be reverse-tapered sloped surfaces, and the cross-section of the separator SP may have an inverted trapezoidal shape. An angle formed by the reverse-tapered sloped surface of the separator SP and the upper surface of the substrate 100 may be 30° or less. The thickness of the separator SP may be about 2 μm to about 4 μm. In an embodiment, the thickness of the separator SP may be about 3 μm. However, the disclosure is not limited thereto and an angle formed by the lateral surface of the separator SP and the upper surface of the substrate 100 may be 30° or more, and the thickness of the separator SP may be 3 μm or more. The width of the separator SP may be less than or equal to the width of the inorganic bank layer 115 disposed under the separator SP. The intermediate layer 220 described below may be disconnected or separated due to the shape and the opening of the separator SP. Likewise, the separator SP may disconnect the opposite electrode 230 and/or a capping layer (not shown) described below.

The separator SP may include an organic insulating material or a photosensitive material. In an embodiment, in the case where the separator SP includes an organic insulating material, the separator SP may include the same material as a material of the first organic insulating layer 109 and/or the second organic insulating layer 111. As an example, the separator SP may include an organic insulating material such as acryl, benzocyclobutene (BCB), polyimide, and/or hexamethyldisiloxane (HMDSO). In another embodiment, in the case where the separator SP includes a photosensitive material, the separator SP may include photosensitive resin. As an example, the separator SP may include a negative photoresist.

The intermediate layer 220 and the opposite electrode 230 may be disposed on the separator SP and the sub-pixel electrode 210 to overlap the sub-pixel electrode 210. The intermediate layer 220 may overlap and contact the inner surface of the sub-pixel electrode 210, and the opposite electrode 230 may overlap the intermediate layer 220. A stack structure of the sub-pixel electrode 210, the intermediate layer 220, and the opposite electrode 230 may correspond to the light-emitting diode ED. The intermediate layer 220 may include the first intermediate layer 1220, the second intermediate layer 2220, and the third intermediate layer 3220, wherein the first intermediate layer 1220 is arranged in the first sub-pixel P1, the second intermediate layer 2220 is arranged in the second sub-pixel P2, and the third intermediate layer 3220 is arranged in the third sub-pixel P3. The opposite electrode 230 may include the first opposite electrode 1230, the second opposite electrode 2230, and the third opposite electrode 3230, wherein the first opposite electrode 1230 is arranged in the first sub-pixel P1, the second opposite electrode 2230 is arranged in the second sub-pixel P2, and the third opposite electrode 3230 is arranged in the third sub-pixel P3.

The intermediate layer 220 may include an emission layer 222 as shown in FIG. 5. The intermediate layer 220 may include a common layer disposed between the sub-pixel electrode 210 and the emission layer 222 and/or between the emission layer 222 and the opposite electrode 230. Hereinafter, a common layer disposed between the sub-pixel electrode 210 and the emission layer 222 is referred to as a first common layer 221, and a common layer the emission layer 222 and the opposite electrode 230 is referred to as a second common layer 223.

The emission layer 222 may include a polymer organic material or a low-molecular weight organic material emitting light having a preset color (red, green, or blue). In another embodiment, the emission layer 222 may include an inorganic material or quantum dots. Here, the emission layer of the first intermediate layer 1220, the emission layer of the second intermediate layer 2220, and the emission layer of the third intermediate layer 3220 may be configured to emit light of different colors.

The first common layer 221 may include a hole transport layer (HTL) and/or a hole injection layer (HIL). The second common layer 223 may include an electron transport layer (ETL) and/or an electron injection layer (EIL). The first common layer 221 and the second common layer 223 may each include an organic material.

The intermediate layer 220 may have a single stack structure including a single emission layer, or a tandem structure, which is a multi-stack structure including multiple emission layers. In the case where the intermediate layer 220 has a tandem structure, a charge generation layer CGL may be disposed between the stacks.

The opposite electrode 230 may include a conductive material having a low work function. As an example, the opposite electrode 230 may include a (semi) transparent layer including silver (Ag), magnesium (Mg), aluminum (Al), platinum (Pt), palladium (Pd), gold (Au), nickel (Ni), neodymium (Nd), and iridium (Ir), chromium (Cr), lithium (Li), calcium (Ca), and/or an alloy thereof. In another embodiment, the opposite electrode 230 may further include a layer on the (semi) transparent layer, the layer including ITO, IZO, ZnO, and/or In₂O₃.

Referring to FIG. 4 again, the intermediate layer 220 may overlap and contact the sub-pixel electrode 210 through the first to third openings OP1, OP2, and OP3 of the separator SP and the openings of the inorganic bank layer 115. The width of the emission area of the light-emitting diode ED may be substantially the same as the width of the opening of the inorganic bank layer 115.

Because the intermediate layer 220 and the opposite electrode 230 are deposited without a separate mask, a deposition material for forming the intermediate layer 220 and a deposition material for forming the opposite electrode 230 may form a dummy intermediate layer and a dummy opposite electrode through the separator SP. As described above, because the two opposite sides of the separator SP includes the reverse-tapered sloped surface, the dummy intermediate layer may be disconnected (or separated) one more time through the separator. For example, the dummy intermediate layer may include a first portion 220b of the dummy intermediate layer and a second portion 220c of the dummy intermediate layer, and the dummy opposite electrode may include a first portion 230b of the dummy opposite electrode and a second portion 230c of the dummy opposite electrode.

The intermediate layer 220, the first portion 220b of the dummy intermediate layer, and the second portion 220c of the dummy intermediate layer may be separated and apart from each other, and the opposite electrode 230, the first portion 230b of the dummy opposite electrode, and the second portion 230c of the dummy opposite electrode may be separated and apart from each other. The intermediate layer 220, the first portion 220b of the dummy intermediate layer, and the second portion 220c of the dummy intermediate layer may include the same material and/or the same number of sub-layers (e.g., the first common layer, the emission layer, and the second common layer). The opposite electrode 230, the first portion 230b of the dummy opposite electrode, and the second portion 230c of the dummy opposite electrode may include the same material.

For example, a deposition material for forming the first intermediate layer 1220 in the first sub-pixel P1 may form not only the first intermediate layer 1220 on the inner surface of the first separator SP1 but also the first portion 1220b of the first dummy intermediate layer on the first separator SP1, and the second portion 1220c of the first dummy intermediate layer on the outer surface of the first separator SP1. In the specification, the inner surface of the separator SP denotes the first to third openings OP1, OP2, and OP3 of each separator, and the outer surface of the separator SP denotes the opposite lateral surfaces of the first to third openings OP1, OP2, and OP3 of each separator. Likewise, a deposition material for forming the second intermediate layer 2220 in the second sub-pixel P2 may form not only the second intermediate layer 2220 on the inner surface of the second separator SP2 but also the first portion 2220b of the second dummy intermediate layer on the second separator SP2, and the second portion 2220c of the second dummy intermediate layer on the outer surface of the second separator SP2. A deposition material for forming the third intermediate layer 3220 in the third sub-pixel P3 may form not only the third intermediate layer 3220 on the inner surface of the third separator SP3 but also the first portion 3220b of the third dummy intermediate layer on the third separator SP3, and the second portion 3220c of the third dummy intermediate layer on the outer surface of the third separator SP3.

A deposition material for forming the first opposite electrode 1230 in the first sub-pixel P1 may form not only the first opposite electrode 1230 on the inner surface of the first separator SP1 but also the first portion 1230b of the first dummy opposite electrode on the first separator SP1, and the second portion 1230c of the first dummy opposite electrode on the outer surface of the first separator SP1. Likewise, a deposition material for forming the second opposite electrode 2230 in the second sub-pixel P2 may form not only the second opposite electrode 2230 on the inner surface of the second separator SP2 but also the first portion 2230b of the second dummy opposite electrode on the second separator SP2, and the second portion 2230c of the second dummy opposite electrode on the outer surface of the second separator SP2. A deposition material for forming the third opposite electrode 3230 in the third sub-pixel P3 may form not only the third opposite electrode 3230 on the inner surface of the third separator SP3 but also the first portion 3230b of the third dummy opposite electrode on the third separator SP3, and the second portion 3230c of the third dummy opposite electrode on the outer surface of the third separator SP3.

The second portion 220c of the dummy intermediate layer and the second portion 230c of the dummy opposite electrode may be arranged between the separators SP apart from each other. In addition, the second portion 1220c of the first dummy intermediate layer and the second portion 2220c of the second dummy intermediate layer may be apart from each other, and the second portion 2220c of the second dummy intermediate layer and the second portion 3220c of the third dummy intermediate layer may be apart from each other. Likewise, the second portion 1230c of the first dummy opposite electrode and the second portion 2230c of the second dummy opposite electrode may be apart from each other, and the second portion 2230c of the second dummy opposite electrode and the second portion 3230c of the third dummy opposite electrode may be apart from each other. For example, the second portions 220c of the dummy intermediate layer surrounding each sub-pixel may be apart from each other, and the second portions 230c of the dummy opposite electrodes surrounding each sub-pixel may be apart from each other.

In an embodiment, the first portion 220b of the dummy intermediate layer may be disposed on the separator SP, and the first portion 230b of the dummy opposite electrode may be disposed on the first portion 220b of the dummy intermediate layer. The second portion 220c of the dummy intermediate layer may be disposed on the second organic insulating layer 111, and the second portion 230c of the dummy opposite electrode may be disposed on the second portion 220c of the dummy intermediate layer. However, the disclosure is not limited thereto, and in a region of the non-sub-pixel area NPA in which the auxiliary electrode AE is connected, the second portion 220c of the dummy intermediate layer and the second portion 230c of the dummy opposite electrode may be disposed on the inorganic bank layer 115 and the auxiliary electrode AE.

Among layers formed on the substrate 100, a layer including an organic material may serve as a transmission path of foreign substance such as moisture, and foreign substance such as moisture may damage the light-emitting diode. As in the display apparatus of FIG. 4, in the case where the separator SP disconnects the intermediate layer 220 and the opposite electrode 230, impurities may be prevented from progressing toward the first to third light-emitting diodes ED1, ED2, and ED3 through the intermediate layer 220 and the like. Particularly, because the two opposite sides of the separator SP include the reverse-tapered sloped surfaces, the first portion 220b of the dummy intermediate layer and the second portion 220c of the dummy intermediate layer may be separated from each other, and thus, the organic material layer such as the intermediate layer 220 may be separated one more time. For example, because a double anchor structure may be formed through the separator SP, contaminants penetrating the light-emitting diode ED may be reduced. Accordingly, in the display apparatus according to an embodiment, because contaminants such as moisture are prevented from penetrating the light-emitting diode, layer-floating defects of an encapsulation layer 500 and pixel shrinkage defects due to oxidation of the opposite electrode 230 may be reduced. Furthermore, because the second portions 220c of the dummy intermediate layer are apart from each other, and the second portions 230c of the dummy opposite electrode are apart from each other, effects of suppressing defect growth such as black spots progressing through the dummy intermediate layer or the dummy opposite electrode may be simultaneously implemented.

The edge or outer portion (or neighboring portion) of the opposite electrode 230 may extend beyond the edge or outer portion (or neighboring portion) of the intermediate layer 220 and directly contact the lateral surface of the auxiliary electrode AE. Accordingly, because the auxiliary electrode AE is electrically connected to the auxiliary line VSL (see FIG. 2A), the opposite electrode 230 may be electrically connected to the auxiliary line VSL. For example, because the auxiliary electrode AE is connected to the auxiliary line VSL and may have the same voltage level as a voltage of the auxiliary line VSL, the opposite electrode 230 connected to the auxiliary electrode AE may be configured to receive the common voltage ELVSS. As described above, because the auxiliary electrodes AE surrounding respective sub-pixels have portions connected to each other, the auxiliary electrodes AE may have the same voltage level. Accordingly, the first opposite electrode 1230, the second opposite electrode 2230, and the third opposite electrode 3230 connected to the auxiliary electrode AE may each have the same voltage level as a voltage (e.g., the common voltage) provided by the auxiliary line VSL.

A capping layer (not shown) may be disposed on the opposite electrode 230, the first portion 230b of the dummy opposite electrode, and the second portion 230c of the dummy opposite electrode. The capping layer may improve an external light-emission efficiency of the light-emitting diode ED based on a constructive interference principle. The capping layer may be an organic capping layer including an organic material, an inorganic capping layer including an inorganic material, or a composite capping layer including an organic material and an inorganic material.

The encapsulation layer 500 may be disposed on the light-emitting diode ED. The encapsulation layer 500 may include at least one inorganic encapsulation layer and at least one organic encapsulation layer. In an embodiment, it is shown in FIG. 4 that the encapsulation layer 500 includes the first inorganic encapsulation layer 510, an organic encapsulation layer 520 on the first inorganic encapsulation layer 510, and a second inorganic encapsulation layer 530 on the organic encapsulation layer 520.

The first inorganic encapsulation layer 510 and the second inorganic encapsulation layer 530 may include at least one inorganic material from among aluminum oxide, titanium oxide, tantalum oxide, hafnium oxide, zinc oxide, silicon oxide, silicon nitride, and silicon oxynitride and be deposited using chemical vapor deposition. The first and second inorganic encapsulation layer 510 and 530 may include a single layer or a multi-layer including the above materials. The organic encapsulation layer 520 may include a polymer-based material. The polymer-based material may include an acryl-based resin, an epoxy-based resin, polyimide, and/or polyethylene. In an embodiment, the organic encapsulation layer 520 may include acrylate.

The first inorganic encapsulation layer 510 having a relatively excellent step coverage may cover the reverse-tapered sloped surface which is the lateral surface of the separator SP. For example, the first inorganic encapsulation layer 510 may cover the first to third openings OP1, OP2, and OP3 of the separators SP and cover the outer surfaces of the separators SP. In an embodiment, the first inorganic encapsulation layer 510 may be continuously formed to overlap (or cover) the upper surface of the second portion 230c of the dummy opposite electrode, the outer surface of the separator SP, the upper surface and the lateral surface of the first portion 230b of the dummy opposite electrode, the lateral surface of the first portion 220b of the dummy intermediate layer, the inner surface of the separator SP, and the upper surface of the opposite electrode 230. The first inorganic encapsulation layer 510 may include a first sub-pixel inorganic encapsulation layer 1510 arranged in the first sub-pixel P1, a second sub-pixel inorganic encapsulation layer 2510 arranged in the second sub-pixel P2, and a third sub-pixel inorganic encapsulation layer 3510 arranged in the third sub-pixel P3.

The first sub-pixel inorganic encapsulation layer 1510, the second sub-pixel inorganic encapsulation layer 2510, and the third sub-pixel inorganic encapsulation layer 3510 may be apart from each other. For example, there may be a region in the non-sub-pixel area NPA in which the first inorganic encapsulation layer 510 is not arranged, and an end of each first inorganic encapsulation layer 510 may be in contact with the organic encapsulation layer 520. Accordingly, the first inorganic encapsulation layer 510 may be configured to suppress the growth of defects by forming a structure sealing each sub-pixel while surrounding each sub-pixel.

The organic encapsulation layer 520 may be located on the first inorganic encapsulation layer 510 and may fill at least a portion of the opening OP of the separator SP. The second inorganic encapsulation layer 530 is disposed on the organic encapsulation layer 520.

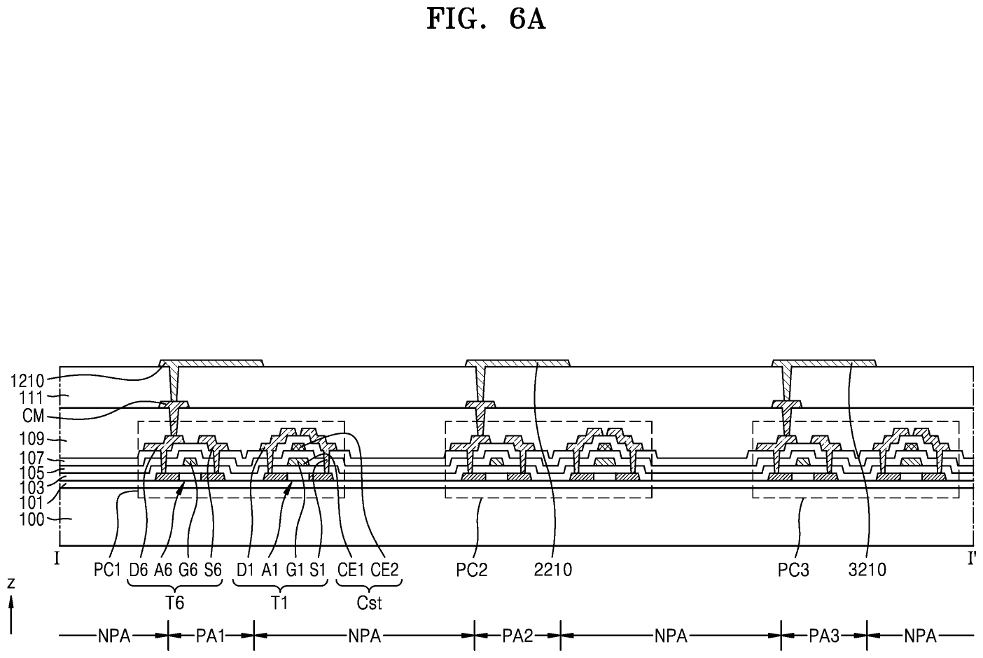

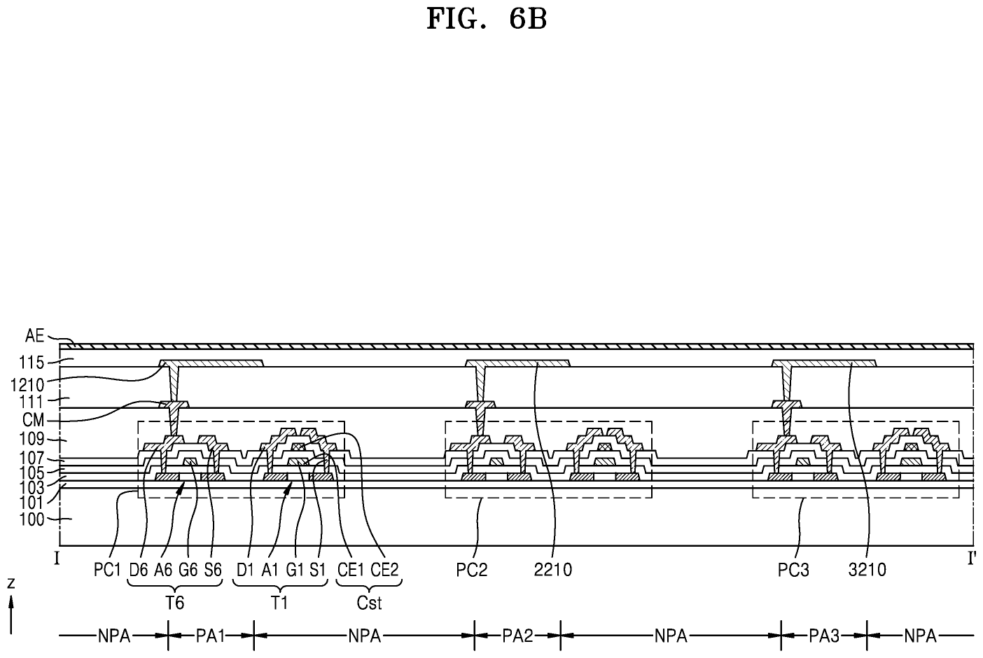

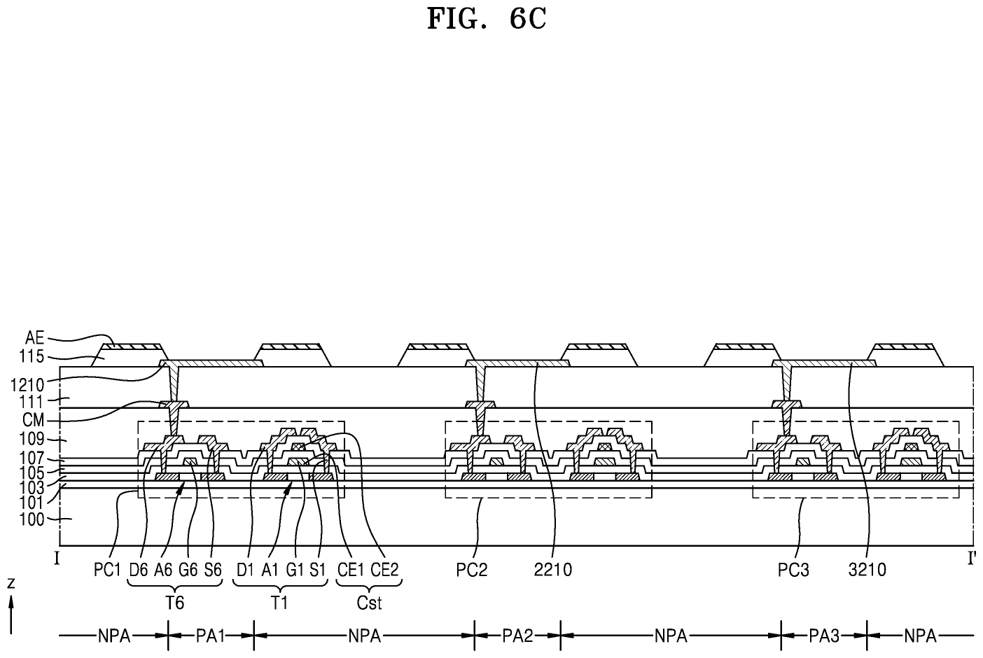

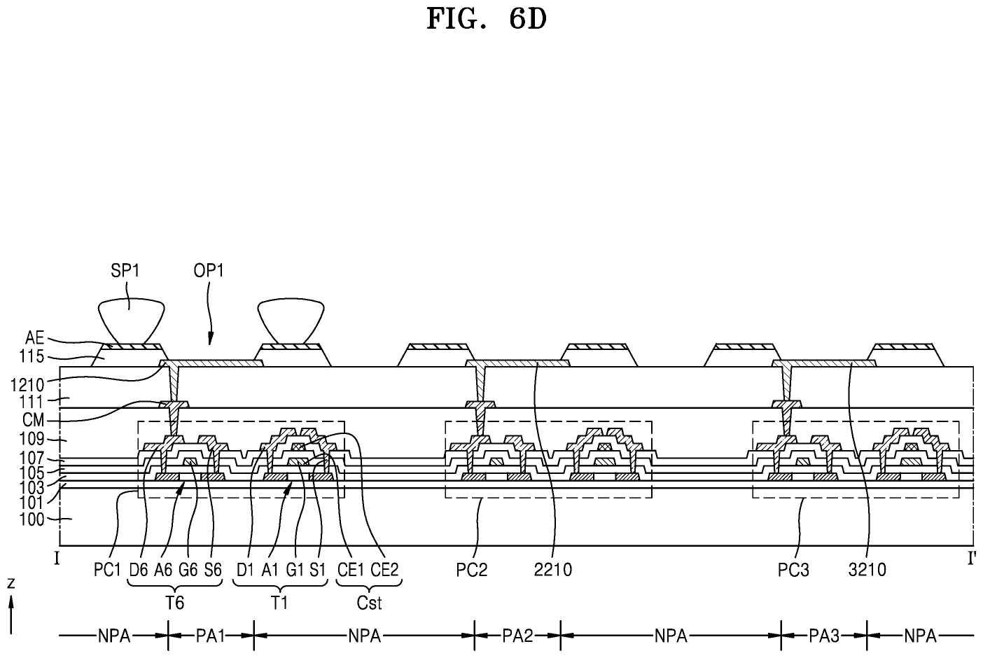

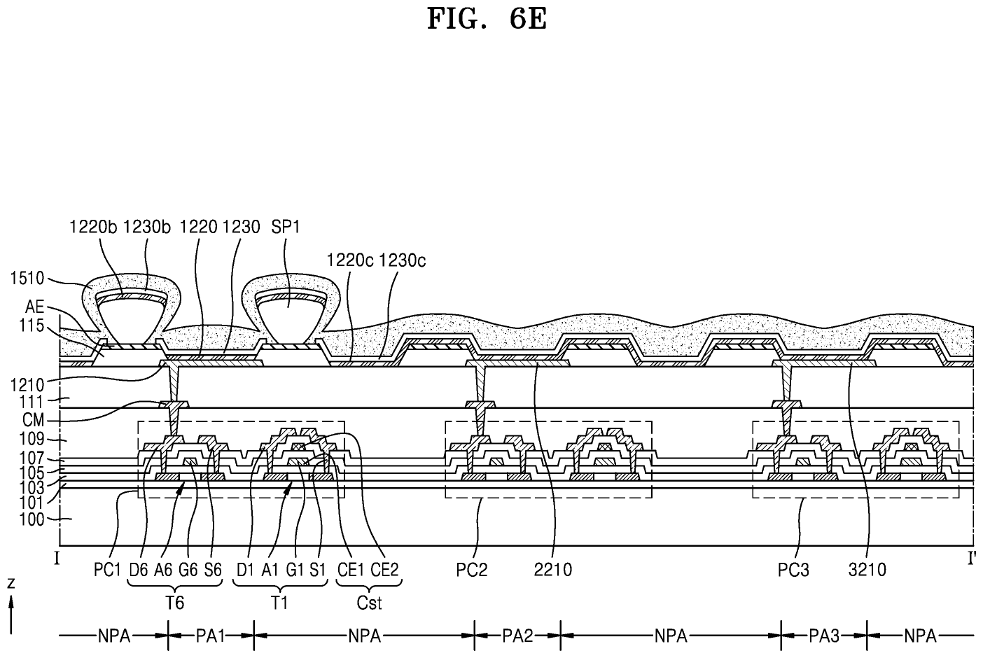

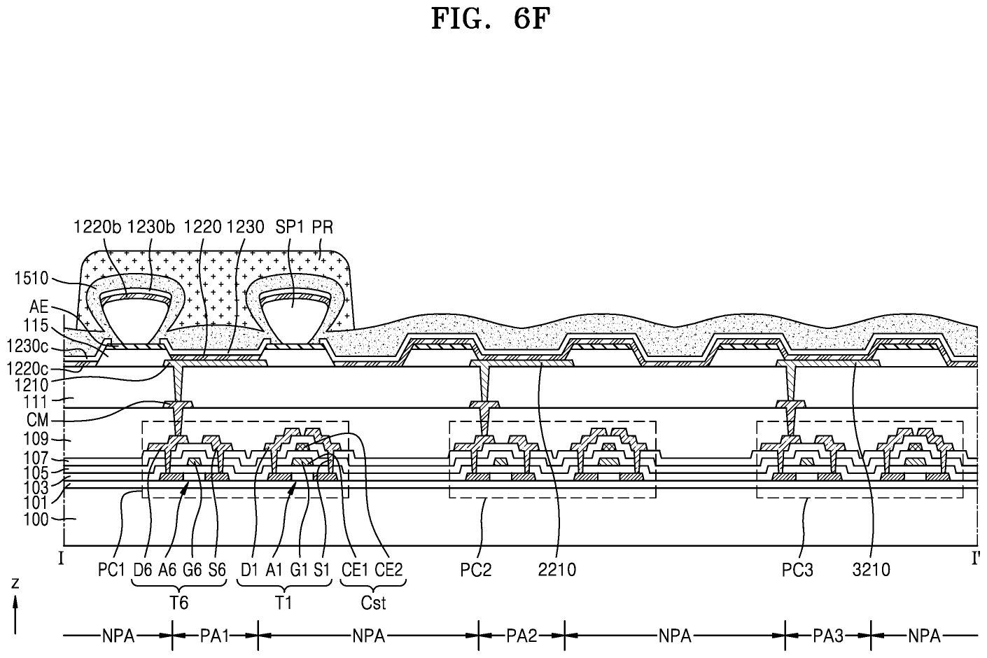

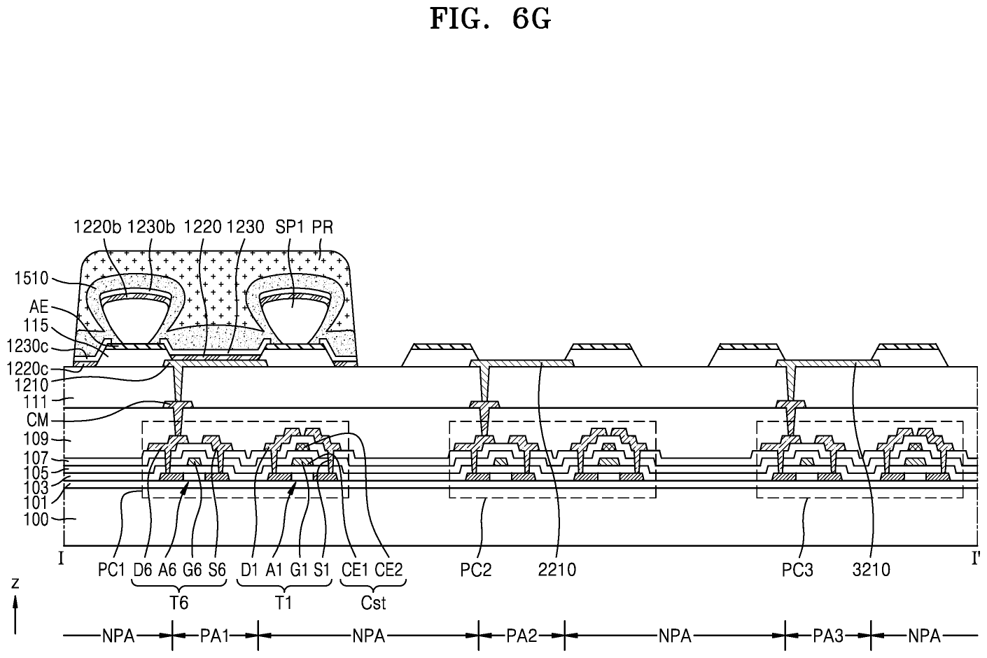

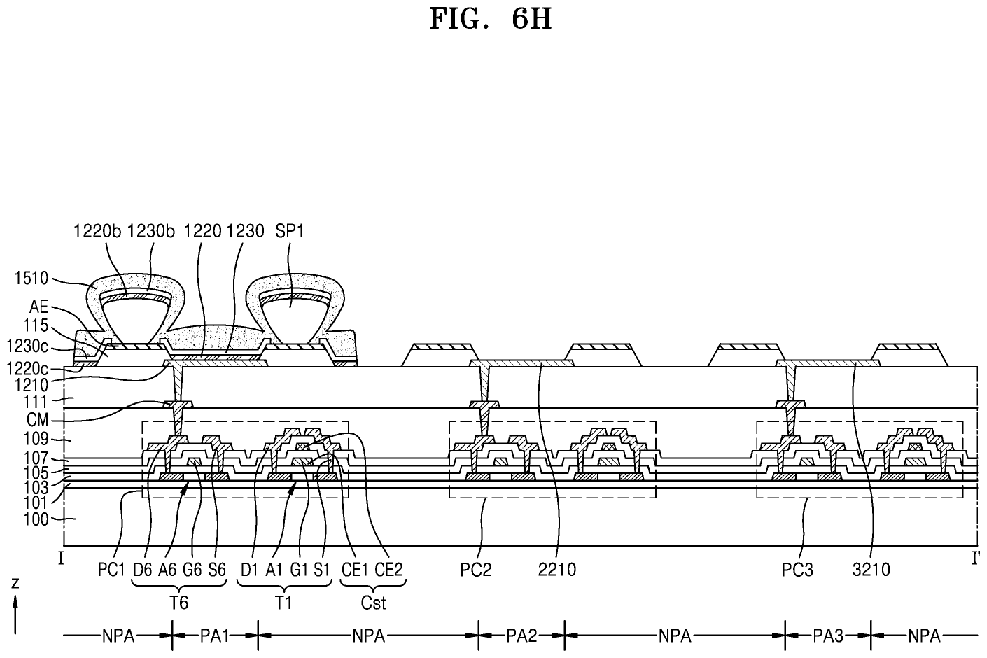

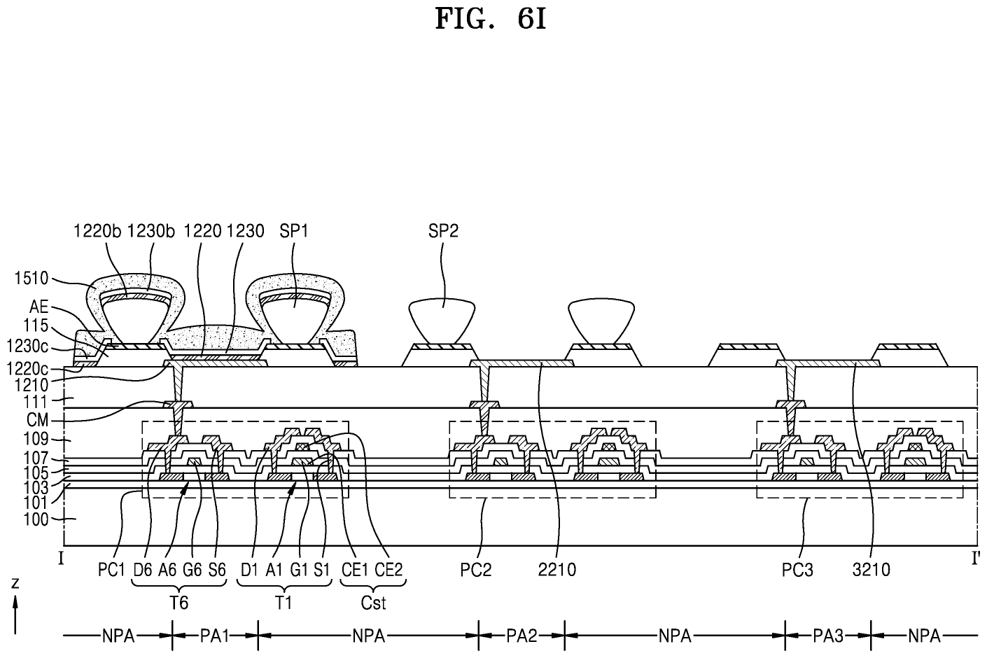

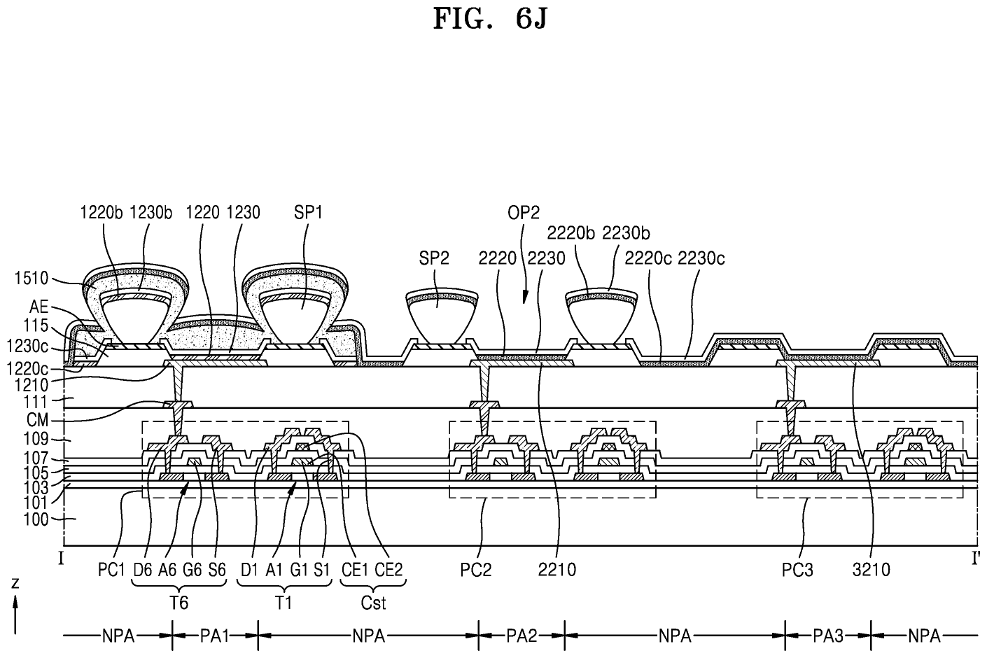

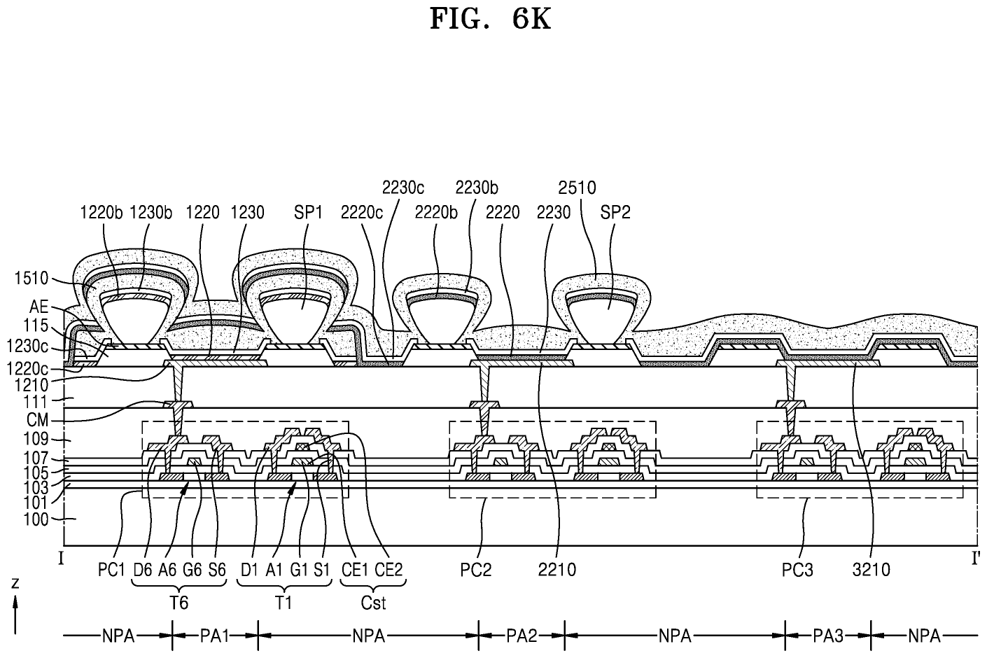

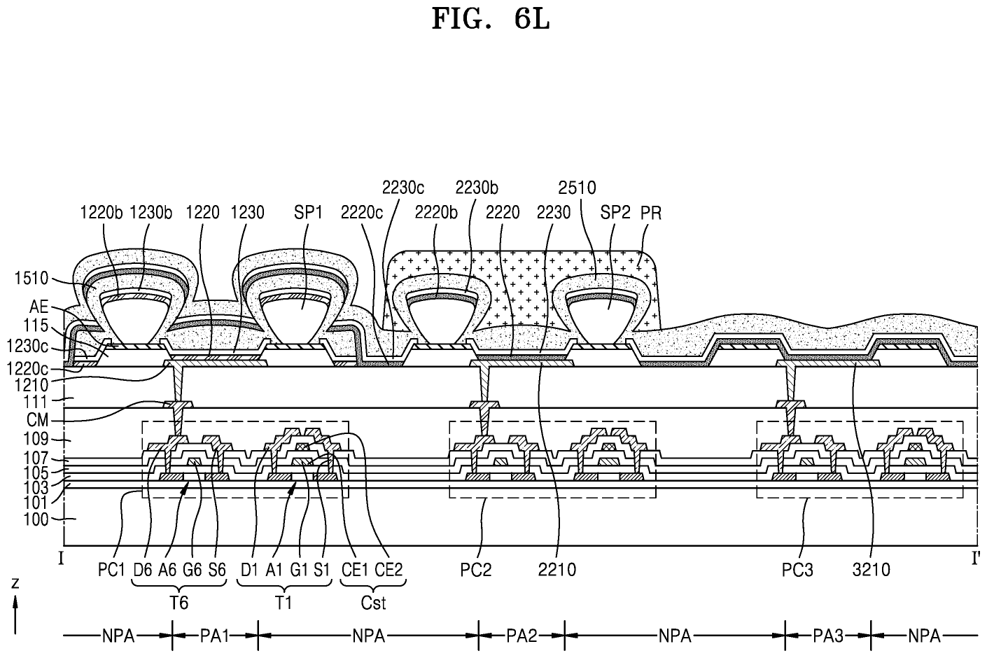

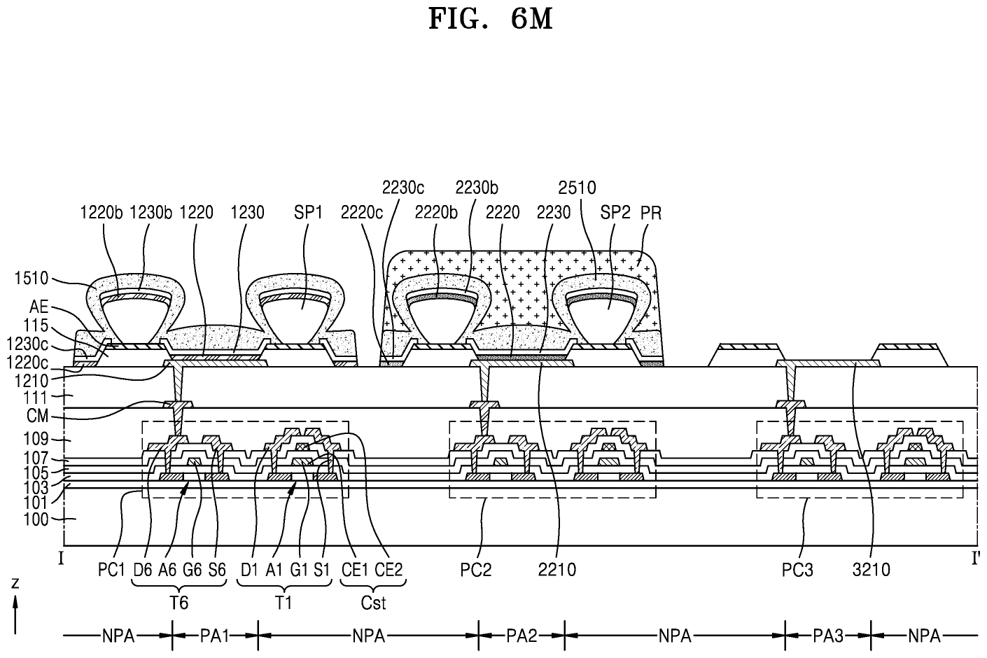

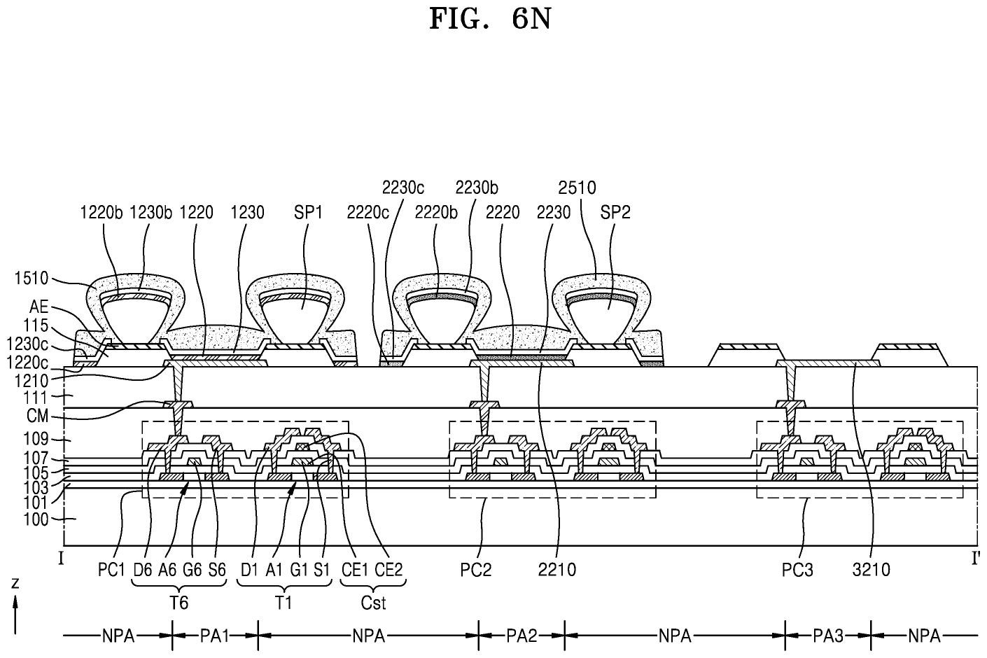

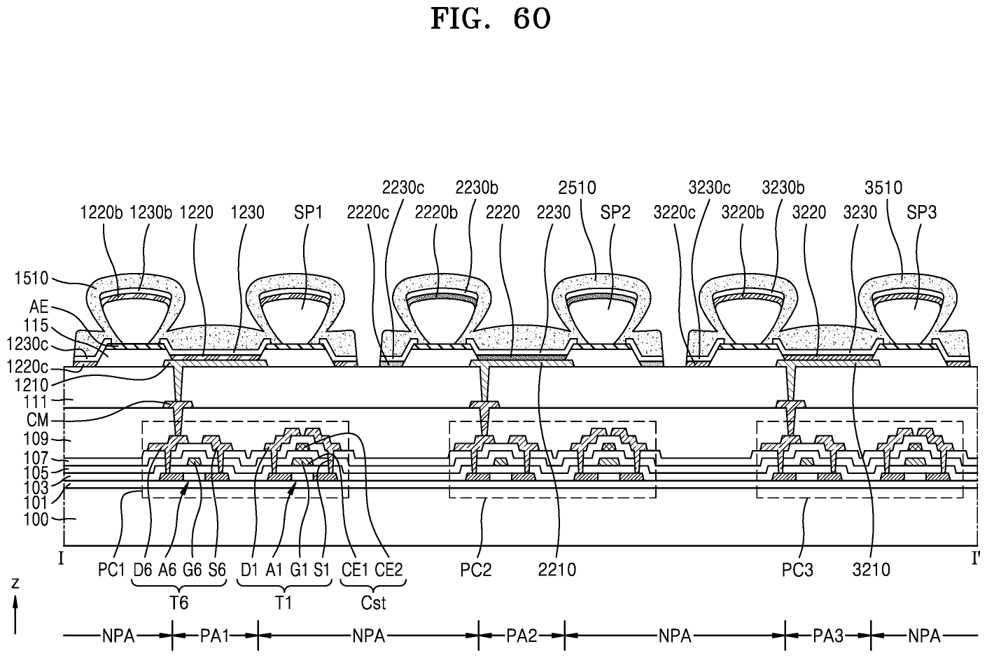

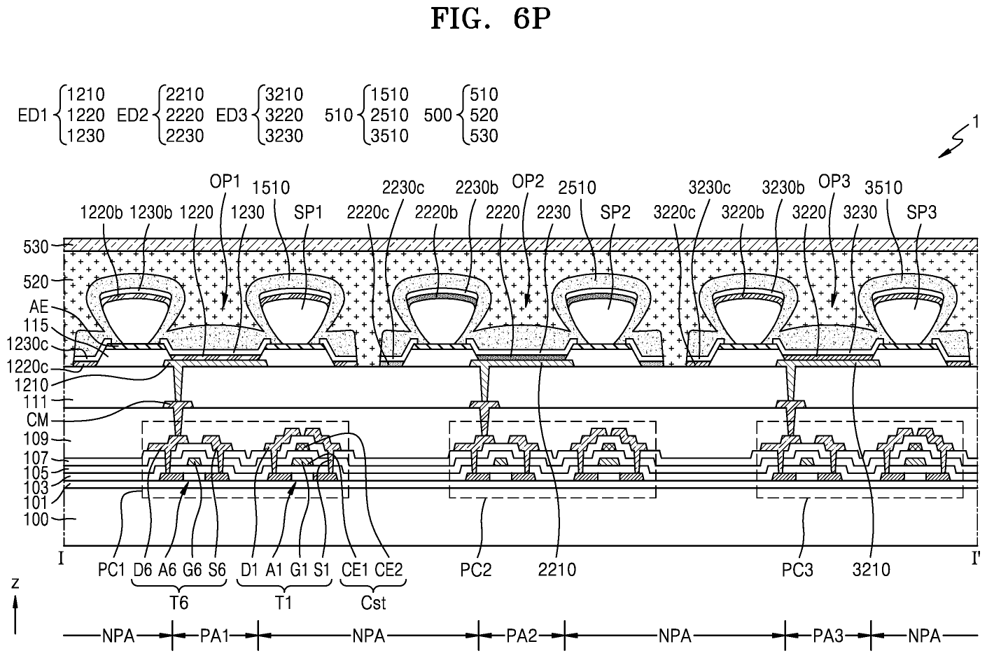

FIGS. 6A to 6P are schematic cross-sectional views showing states corresponding to a process of manufacturing a display apparatus according to an embodiment.

First, referring to FIG. 6A, as described above, the display apparatus 1 may include the first to third sub-pixel areas PA1, PA2, and PA3, and the non-sub-pixel area NPA between adjacent sub-pixel areas. The first to third sub-pixel circuits PC1, PC2, and PC3 may be formed on the substrate 100 corresponding to respective sub-pixel areas. The first to third sub-pixel circuits PC1, PC2, and PC3 may each include the transistor and the storage capacitor described above with reference to FIGS. 2A and 2B. In an embodiment, it is shown in FIG. 6A that the first to third sub-pixel circuits PC1, PC2, and PC3 each have the same structure as the structure of the first to third sub-pixel circuits PC1, PC2, and PC3 (see FIG. 3) described with reference to FIG. 4, and a specific structure is the same as that described above.

The first organic insulating layer 109 and the second organic insulating layer 111 may be arranged to cover the sub-pixel circuit PC, and the first to third sub-pixel electrodes 1210, 2210, and 3210 may be formed on the second organic insulating layer 111. The first to third sub-pixel electrodes 1210, 2210, and 3210 may be respectively connected to the connection metals CM disposed between the first organic insulating layer 109 and the second organic insulating layer 111 and be respectively electrically connected to the first to third sub-pixel circuits PC1, PC2, and PC3. Specifically, the first sub-pixel electrode 1210 may be arranged in the first sub-pixel area PA1 and connected to the first sub-pixel circuit PC1 through the connection metal CM, the second sub-pixel electrode 2210 may be arranged in the second sub-pixel area PA2 and connected to the second sub-pixel circuit PC2 through the connection metal CM, and the third sub-pixel electrode 3210 may be arranged in the third sub-pixel area PA3 and connected to the third sub-pixel circuit PC3 through the connection metal CM.

Referring to FIG. 6B, an inorganic bank layer 115 may be formed on the structure shown in FIG. 6A. The inorganic bank layer 115 may be formed on the substrate 100 in its entirety. As an example, the inorganic bank layer 115 may overlap the first to third sub-pixel electrodes 1210, 2210, and 3210 and be in direct contact with the upper surface of the second organic insulating layer 111 where the first to third sub-pixel electrodes 1210, 2210, and 3210 are not present. The inorganic bank layer 115 may cover the lateral surface of each of the first to third sub-pixel electrodes 1210, 2210, and 3210.

The auxiliary electrode AE may be formed on the inorganic bank layer 115. Like the inorganic bank layer 115, the auxiliary electrode AE may be formed on the substrate 100 entirely. The auxiliary electrode AE is an electrode connected to the auxiliary line VSL (see FIG. 2A). The auxiliary electrode AE may be configured to receive a voltage corresponding to the common voltage ELVSS through the auxiliary line VSL. Materials of the inorganic bank layer 115 and the auxiliary electrode AE may be the same as those described above with reference to FIG. 4.

Referring to FIG. 6C, a portion of the inorganic bank layer 115 and the auxiliary electrode AE may be removed. Specifically, a photoresist (not shown) may be formed on the inorganic bank layer 115 and the auxiliary electrode AE. The photoresist may be formed to surround the first to third sub-pixel electrodes 1210, 2210, and 3210 in a plan view and may include openings overlapping the first to third sub-pixel electrodes 1210, 2210, and 3210. A portion of the inorganic bank layer 115 and the auxiliary electrode AE may be removed using the photoresist as a mask. A portion of the inorganic bank layer 115 and the auxiliary electrode AE may be removed through the opening of the photoresist by dry etching.

A portion of the inorganic bank layer 115 and the auxiliary electrode AE may be removed by the dry etching process, and regions surrounding the first to third sub-pixel electrodes 1210, 2210, and 3210 may remain. Although the inorganic bank layer 115 surrounding each of the first to third sub-pixel electrodes 1210, 2210, and 3210, and the auxiliary electrodes AE may be apart from each other, the inorganic bank layer 115 and the auxiliary electrodes AE may be connected to each other in some regions. The central portion of each of the first to third sub-pixel electrodes 1210, 2210, and 3210 may be exposed through the dry etching process. The exposed region of each of the first to third sub-pixel electrodes 1210, 2210, and 3210 may correspond to the emission area.

After that, the photoresists on the inorganic bank layer 115 and the auxiliary electrodes AE are removed.

Referring to FIG. 6D, the first separator SP1 may be formed on the inorganic bank layer 115 and the auxiliary electrode AE each surrounding the first sub-pixel electrode 1210. For example, the first separator SP1 may be arranged to overlap the inorganic bank layer 115 and the auxiliary electrode AE and arranged to surround the first sub-pixel electrode 1210 in a plan view. The first separator SP1 may have an isolated island shape in a plan view and a ring shape surrounding the first sub-pixel electrode 1210.

The first separator SP1 may have a reverse-tapered shape in cross-section. For example, the first separator SP1 may have a shape in which a width of an upper surface thereof is greater than a width of a bottom surface thereof, and two opposite sides of the first separator SP1 may include a reverse-tapered sloped surface. A material deposited on the first separator SP1 may be disconnected by the shape of the first separator SP1.

A material of the first separator SP1 may be the same as that described above with reference to FIG. 4. In an embodiment, in the case where the first separator SP1 includes a photosensitive material, for example, a negative photoresist, the first separator SP1 may be formed by coating a negative photoresist such as polyimide, polyacryl, polymer, and/or the like and patterning the photoresist in a dam shape using photolithography. Specifically, in case that a separator material layer forming the first separator SP1 is exposed using an ultraviolet (UV) ray, because the upper portion of the separator material layer absorbs the UV relatively more compared the lower portion, the exposed region may be formed such that an upper portion thereof is wide and a lower portion thereof is narrow. The first separator SP1 may be formed by developing the separator material layer passing through the exposure process. Accordingly, the first separator SP1 may have a cross-sectional shape of an inverted trapezoid in which a width of an upper surface thereof is wider than a width of a bottom surface thereof due to a difference in energy absorption during exposure.

Referring to FIG. 6E, the first intermediate layer 1220, the first opposite electrode 1230, and the first sub-pixel inorganic encapsulation layer 1510 may be formed on the structure of FIG. 6D. As described above with reference to FIG. 5, the first intermediate layer 1220 may have a multi-layered structure including the first common layer, the emission layer, and/or the second common layer. The first intermediate layer 1220 and the first opposite electrode 1230 may each be formed by deposition methods such as thermal deposition.

The first intermediate layer 1220 may be formed through the first opening OP1 of the first separator SP1. A material forming the first intermediate layer 1220 may be deposited on the first sub-pixel electrode 1210 through the first opening OP1 to form the first intermediate layer 1220. However, because the material forming the first intermediate layer 1220 may be formed on the substrate 100 entirely, the material forming the first intermediate layer 1220 may be deposited also on the upper surface of the first separator SP1 and deposited also on the outer surface of the first separator SP1. As an example, a portion of the material forming the first intermediate layer 1220 deposited on the upper surface of the first separator SP1 may be denoted by the first portion 1220b of the first dummy intermediate layer, and a portion of the material forming the first intermediate layer 1220 deposited on the outer portion of the first separator SP1 may be denoted by the second portion 1220c of the first dummy intermediate layer. For example, due to the first separator SP1 having a reverse-tapered shape, the first intermediate layer 1220 may be separated from the first portion 1220b of the first dummy intermediate layer, and the first portion 1220b of the first dummy intermediate layer may be separated from the second portion 1220c of the first dummy intermediate layer. The second portion 1220c of the first dummy intermediate layer may extend to a region entirely except the first sub-pixel area PA1 and the first separator SP1. For example, the second portion 1220c of the first dummy intermediate layer may be deposited also on the second sub-pixel area PA2, the third sub-pixel area PA3, and the non-sub-pixel area NPA. Accordingly, a partial region of the second portion 1220c of the first dummy intermediate layer may be deposited on the second organic insulating layer 111. The first intermediate layer 1220, the first portion 1220b of the first dummy intermediate layer, and the second portion 1220c of the first dummy intermediate layer may include the same material and/or the same number of sub-layers (e.g., the first common layer, the emission layer, and the second common layer).

In the specification, the inner surface of the first separator SP1 may denote an inner surface region facing the first opening OP1 of the first separator SP1, and the outer surface of the first separator SP1 may denote an outer surface region that is opposite to the inner surface of the first separator SP1.

Likewise, the first opposite electrode 1230 may be formed through the first opening OP1 of the first separator SP1. A material forming the first opposite electrode 1230 may be deposited on the first intermediate layer 1220 through the first opening OP1 to form the first opposite electrode 1230. The first opposite electrode 1230 may overlap the first intermediate layer 1220. During the deposition process, an incident angle of a material forming the first opposite electrode 1230 may be different from an incident angle of a material forming the first intermediate layer 1220. Accordingly, during the process of depositing the first opposite electrode 1230, the outer portion (or the peripheral portion) of the first opposite electrode 1230 may be in direct contact with the auxiliary electrode AE facing the first opening OP1. In other words, the outer portion of the first opposite electrode 1230 may extend to pass across the outer portion of the first intermediate layer 1220 and be in direct contact with the lateral surface and/or the upper surface of the auxiliary electrode AE.

However, because the material forming the first opposite electrode 1230 may be formed on the substrate 100 in its entirety, the material forming the first opposite electrode 1230 may be deposited also on the upper surface of the first separator SP1 and deposited also on the outer surface of the first separator SP1. As an example, a portion of the material forming the first opposite electrode 1230 deposited on the upper surface of the first separator SP1 may be denoted by the first portion 1220b of the first dummy opposite electrode, and a portion of the material forming the first opposite electrode 1230 deposited on the outer portion of the first separator SP1 may be denoted by the second portion 1230c of the first dummy opposite electrode. For example, due to the first separator SP1 having a reverse-tapered shape, the first opposite electrode 1230 may be separated from the first portion 1230b of the first dummy opposite electrode, and the first portion 1230b of the first dummy opposite electrode may be separated from the second portion 1230c of the first dummy opposite electrode. The second portion 1230c of the first dummy opposite electrode may extend to a region entirely except the first sub-pixel area PA1 and the first separator SP1. For example, the second portion 1230c of the first dummy opposite electrode may be deposited also on the second sub-pixel area PA2, the third sub-pixel area PA3, and the non-sub-pixel area NPA. The first opposite electrode 1230, the first portion 1230b of the first dummy opposite electrode, and the second portion 1230c of the first dummy opposite electrode may include the same material.

The first sub-pixel inorganic encapsulation layer 1510 may be formed on the first opposite electrode 1230, the first portion 1230b of the first dummy opposite electrode, and the second portion 1230c of the first dummy opposite electrode. The first sub-pixel inorganic encapsulation layer 1510 may include at least one inorganic material from among aluminum oxide, titanium oxide, tantalum oxide, hafnium oxide, zinc oxide, silicon oxide, silicon nitride, and silicon oxynitride and be deposited using chemical vapor deposition. The first sub-pixel inorganic encapsulation layer 1510 having an excellent step coverage may continuously cover the two opposite sides and the upper surface of the first separator SP1. The first sub-pixel inorganic encapsulation layer 1510 may be disposed also on the second portion 1230c of the first dummy opposite electrode and be continuously arranged in also the second sub-pixel area PA2, the third sub-pixel area PA3, and the non-sub-pixel area NPA.

Referring to FIG. 6F, a photoresist PR may be formed in the first sub-pixel area PA1 and a portion of the non-sub-pixel area NPA surrounding the first sub-pixel area PA1. Specifically, the photoresist PR may be formed to overlap the first sub-pixel electrode 1210, the first separator SP1, and a partial region outside the first separator SP1. The photoresist PR may be formed by forming a photosensitive material layer (not shown) on the first sub-pixel inorganic encapsulation layer 1510 and exposing and developing the photosensitive material layer using a mask.

Referring to FIG. 6G, the second portion 1220c of the first dummy intermediate layer, the second portion 1230c of the first dummy opposite electrode, and a portion of the first sub-pixel inorganic encapsulation layer 1510 may be removed using the photoresist PR as a mask. Specifically, in case that the second portion 1220c of the first dummy intermediate layer, the second portion 1230c of the first dummy opposite electrode, and a portion of the first sub-pixel inorganic encapsulation layer 1510 that do not overlap the photoresist PR are removed using the photoresist PR as a mask, a portion of the second portion 1220c of the first dummy intermediate layer, the second portion 1230c of the first dummy opposite electrode, and the first sub-pixel inorganic encapsulation layer 1510 may remain as shown in FIG. 6G.

Referring to FIG. 6H, the photoresist PR may be removed. The first intermediate layer 1220, the first opposite electrode 1230, the first dummy intermediate layers 1220b and 1220c, the first dummy opposite electrodes 1230b and 1230c, and the first sub-pixel inorganic encapsulation layer 1510 that overlap the photoresist PR may have isolated shapes in a plan view.

Referring to FIG. 6I, the second separator SP2 may be formed on the inorganic bank layer 115 and the auxiliary electrode AE each surrounding the second sub-pixel electrode 2210. For example, the second separator SP2 may be arranged to overlap the inorganic bank layer 115 and the auxiliary electrode AE and arranged to surround the second sub-pixel electrode 2210 in a plan view. The second separator SP2 may have an isolated island shape in a plan view and a ring shape surrounding the second sub-pixel electrode 2210. Specific structure and material of the second separator SP2 may be the same as those described above with reference to the first separator SP1 in FIG. 6D.

Referring to FIG. 6J, the second intermediate layer 2220 and the second opposite electrode 2230 may be formed on the structure shown in FIG. 6I. As described above with reference to FIG. 5, the second intermediate layer 2220 may have a multi-layered structure including the first common layer, the emission layer, and/or the second common layer. The second intermediate layer 2220 and the second opposite electrode 2230 may each be formed by deposition methods such as thermal deposition.

The second intermediate layer 2220 may be formed through the second opening OP2 of the second separator SP2. A material forming the second intermediate layer 2220 may be deposited on the second sub-pixel electrode 2210 through the second opening OP2 to form the second intermediate layer 2220. However, because the material forming the second intermediate layer 2220 may be formed on the substrate 100 entirely, the material forming the second intermediate layer 2220 may be deposited also on the upper surface of the second separator SP2 and deposited also on the outer surface of the second separator SP2. As an example, a portion of the material forming the second intermediate layer 2220 deposited on the upper surface of the second separator SP2 may be denoted by the first portion 2220b of the second dummy intermediate layer, and a portion of the material forming the second intermediate layer 2220 deposited on the outer portion of the second separator SP2 may be denoted by the second portion 2220c of the second dummy intermediate layer. For example, due to the second separator SP2 having a reverse-tapered shape, the second intermediate layer 2220 may be separated from the first portion 2220b of the second dummy intermediate layer, and the first portion 2220b of the second dummy intermediate layer may be separated from the second portion 2220c of the second dummy intermediate layer. The second portion 2220c of the second dummy intermediate layer may extend to a region entirely except the second sub-pixel area PA2 and the second separator SP2. For example, the second portion 2220c of the second dummy intermediate layer may be deposited also on the first sub-pixel area PA1, the third sub-pixel area PA3, and the non-sub-pixel area NPA. The second intermediate layer 2220, the second portion 2220b of the second dummy intermediate layer, and the second portion 2220c of the second dummy intermediate layer may include the same material and/or the same number of sub-layers (e.g., the first common layer, the emission layer, and the second common layer).

Likewise, the second opposite electrode 2230 may be formed through the second opening OP2 of the second separator SP2. A material forming the second opposite electrode 2230 may be deposited on the second intermediate layer 2220 through the second opening OP2 to form the second opposite electrode 2230. The second opposite electrode 2230 may overlap the second intermediate layer 2220. During the deposition process, an incident angle of a material forming the second opposite electrode 2230 may be different from an incident angle of a material forming the second intermediate layer 2220. Accordingly, during the process of depositing the second opposite electrode 2230, the outer portion (or the peripheral portion) of the second opposite electrode 2230 may be in direct contact with the auxiliary electrode AE facing the second opening OP2. In other words, the outer portion of the second opposite electrode 2230 may extend to pass across the outer portion of the second intermediate layer 2220 and be in direct contact with the lateral surface and/or the upper surface of the auxiliary electrode AE.

However, because the material forming the second opposite electrode 2230 may be formed on the substrate 100 entirely, the material forming the second opposite electrode 2230 may be deposited also on the upper surface of the second separator SP2 and deposited also on the outer surface of the second separator SP2. As an example, a portion of the material forming the second opposite electrode 2230 deposited on the upper surface of the second separator SP2 may be denoted by the first portion 1230b of the second dummy opposite electrode, and a portion of the material forming the second opposite electrode 2230 deposited on the outer portion of the second separator SP2 may be denoted by the second portion 2230c of the second dummy opposite electrode. For example, due to the second separator SP2 having a reverse-tapered shape, the second opposite electrode 2230 may be separated from the first portion 2230b of the second dummy opposite electrode, and the first portion 2230b of the second dummy opposite electrode may be separated from the second portion 2230c of the second dummy opposite electrode. The second portion 2230c of the second dummy opposite electrode may extend to a region entirely except the second sub-pixel area PA2 and the second separator SP2. For example, the second portion 2230c of the second dummy opposite electrode may be deposited also on the first sub-pixel area PA1, the third sub-pixel area PA3, and the non-sub-pixel area NPA. The second opposite electrode 2230, the first portion 1230b of the first dummy opposite electrode, and the second portion 1230c of the first dummy opposite electrode may include the same material.

Referring to FIG. 6K, the second sub-pixel inorganic encapsulation layer 2510 may be formed on the second opposite electrode 2230, the first portion 2230b of the second dummy opposite electrode, and the second portion 2230c of the second dummy opposite electrode. The second sub-pixel inorganic encapsulation layer 2510 may include at least one inorganic material from among aluminum oxide, titanium oxide, tantalum oxide, hafnium oxide, zinc oxide, silicon oxide, silicon nitride, and silicon oxynitride and be deposited using chemical vapor deposition. The second sub-pixel inorganic encapsulation layer 2510 having an excellent step coverage may continuously cover the two opposite sides and the upper surface of the second separator SP2. The second sub-pixel inorganic encapsulation layer 2510 may be disposed also on the second portion 2230c of the second dummy opposite electrode and be continuously arranged in also the first sub-pixel area PA1, the third sub-pixel area PA3, and the non-sub-pixel area NPA.

Referring to FIG. 6I, the photoresist PR may be formed in the second sub-pixel area PA2 and a portion of the non-sub-pixel area NPA surrounding the second sub-pixel area PA2. Specifically, the photoresist PR may be formed to overlap the second sub-pixel electrode 2210, the second separator SP2, and a partial region outside the second separator SP2. A specific material of the photoresist PR and a method of forming the photoresist PR may be the same as those described with reference to the photoresist PR in FIG. 6F.

Referring to FIG. 6M, the second portion 2220c of the second dummy intermediate layer, the second portion 2230c of the second dummy opposite electrode, and a portion of the second sub-pixel inorganic encapsulation layer 2510 may be removed using the photoresist PR as a mask. Specifically, in case that the second portion 2220c of the second dummy intermediate layer, the second portion 2230c of the second dummy opposite electrode, and a portion of the second sub-pixel inorganic encapsulation layer 2510 that do not overlap the photoresist PR are removed using the photoresist PR as a mask, a portion of the second portion 2220c of the second dummy intermediate layer, the second portion 2230c of the second dummy opposite electrode, and the second sub-pixel inorganic encapsulation layer 2510 may remain as shown in FIG. 6M.

Referring to FIG. 6N, the photoresist PR may be removed. The second intermediate layer 2220, the second opposite electrode 2230, the second dummy intermediate layers 2220b and 2220c, the second dummy opposite electrodes 2230b and 2230c, and the second sub-pixel inorganic encapsulation layer 2510 that overlap the photoresist PR may have isolated shapes in a plan view.

Referring to FIG. 6O, the third separator SP3, the third intermediate layer 3220, the third opposite electrode 3230, and the third sub-pixel inorganic encapsulation layer 3510 may be formed on the structure shown in FIG. 6N. Specific structure, material and forming method of each of the third separator SP3, the third intermediate layer 3220, the third dummy intermediate layers 3220b and 3220c, the third dummy opposite electrodes 3230b and 3230c, and the third sub-pixel inorganic encapsulation layer 3510 may be the same as those described with reference to FIGS. 6D to 6H.

Referring to FIG. 6P, the organic encapsulation layer 520 and the second inorganic encapsulation layer 530 may be formed on the structure shown in FIG. 6O. The organic encapsulation layer 520 may be disposed on the first to third sub-pixel inorganic encapsulation layers 1510, 2510, and 3510 and may fill at least some of the first to third openings OP1, OP2, and OP3. The organic encapsulation layer 520 may be formed by coating monomer on the substrate 100 and curing the monomer. The organic encapsulation layer 520 may cover the first to third separators SP1, SP2, and SP3. The second inorganic encapsulation layer 530 may be formed on the organic encapsulation layer 520 and formed on the substrate 100 entirely. The second inorganic encapsulation layer 530 may be formed by chemical vapor deposition (CVD).

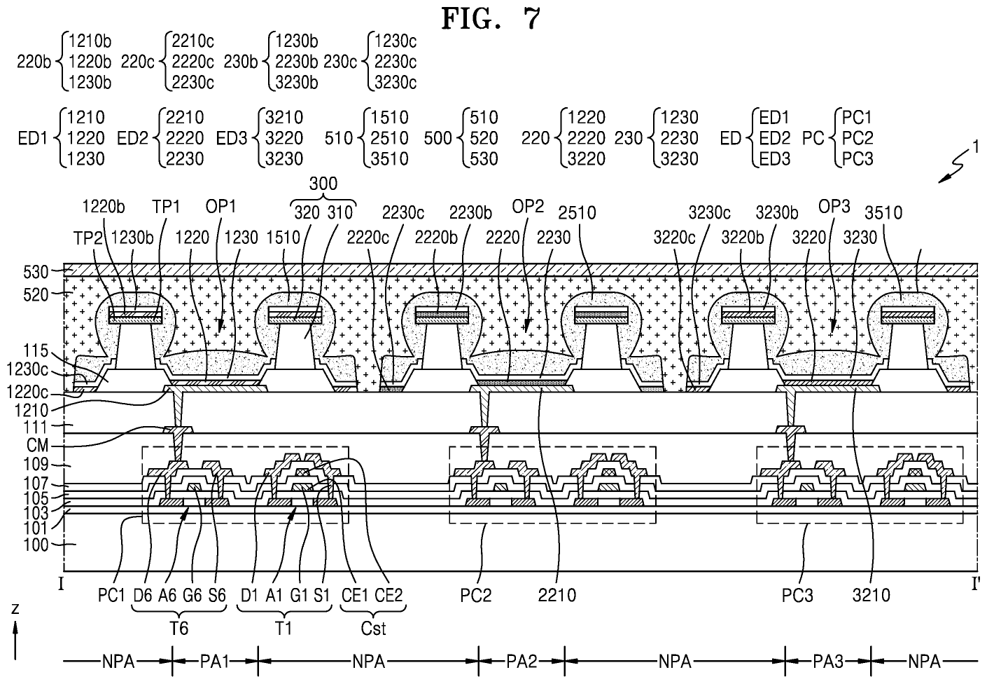

FIG. 7 is a schematic cross-sectional view of a portion of the display apparatus according to another embodiment. Referring to FIG. 7, other characteristics except for the characteristic of a metal bank layer 300 may be the same as those described with reference to FIGS. 4 and 5. Same reference numerals among elements of FIG. 7 are replaced with those previously described with reference to FIG. 5, and differences are described below.

Referring to FIG. 7, the metal bank layer 300 may be disposed on the inorganic bank layer 115. The metal bank layer 300 may include a first metal layer 310 and a second metal layer 320 on the first metal layer 310. The first metal layer 310 and the second metal layer 320 may include different metals. As an example, the first metal layer 310 and the second metal layer 320 may include metals with different etching selectivities. In an embodiment, the first metal layer 310 may include a layer including aluminum (Al), and the second metal layer 320 may include a layer including titanium (Ti).

The thickness of the first metal layer 310 may be greater than the thickness of the second metal layer 320. In an embodiment, the thickness of the first metal layer 310 may be greater than about 5 times the thickness of the second metal layer 320. In another embodiment, the thickness of the first metal layer 310 may be greater than about 6 times, greater than about 7 times, or greater than about 8 times the thickness of the second metal layer 320. In an embodiment, the thickness of the first metal layer 310 may be about 4000 Å to about 8000 Å, and the thickness of the second metal layer 320 may be about 500 Å to about 800 Å. The thickness of the first metal layer 310 may be about 4 times or more, about 5 times or more, or about 6 times or more of the thickness of the inorganic bank layer 115.

The metal bank layer 300 may include first to third openings OP1, OP2, and OP3 respectively overlapping the third to third sub-pixel electrodes 1210, 2210, and 3210. Because the first metal layer 310 and the second metal layer 320 include metals with different etching selectivities, the first to third openings OP1, OP2, and OP3 of the metal bank layer 300 may each have an undercut structure. For example, because the opening of the first metal layer 310 has a large diameter while overlapping the opening of the second metal layer 320, the second metal layer 320 may have a first tip PT1. For example, a portion of the second metal layer 320 facing the first to third openings OP1, OP2, and OP3 may protrude to the first to third openings OP1, OP2, and OP3 from a point at which the lateral surface of the first metal layer 310 facing the first to third openings OP1, OP2, and OP3 meets the bottom surface of the second metal layer 320, and thus, may have an undercut structure. A portion of the second metal layer 320 further protruding to the first to third openings OP1, OP2, and OP3 may correspond to a first tip TP1. The length of the first tip TP1 may be about 2 μm or less. In an embodiment, the length of the first tip TP1 of the second metal layer 320 may be about 0.3 μm to about 1 μm or about 0.3 μm to about 0.7 μm.

The metal bank layer 300 may not extend in the non-sub-pixel area NPA but a portion of the metal bank layer 300 may be removed. In an embodiment, the metal bank layer 300 may be disconnected in the non-sub-pixel area NPA and be arranged apart from the non-sub-pixel area NPA, and the lateral surface of the metal bank layer 300 facing the non-sub-pixel area NPA may also include an undercut structure. As an example, a portion of the second metal layer 320 facing the non-sub-pixel area NPA may protrude to the non-sub-pixel area NPA from a point at which the lateral surface of the first metal layer 310 facing the non-sub-pixel area NPA meets the bottom of the second metal layer 320, and may form an undercut structure. A portion of the second metal layer 320 protruding toward the non-sub-pixel area NPA may correspond to a second tip TP2. The length of the second tip TP2 may be 2 about μm or less. In an embodiment, the length of the second tip TP2 of the second metal layer 320 may be about 0.3 μm to about 1 μm or about 0.3 μm to about 0.7 μm.

The metal bank layers 300 may be apart from each other in the non-sub-pixel area NPA, and because the two opposite sides respectively include the first tip TP1 and the second tip TP2, the metal bank layer 300 may disconnect and separate the intermediate layer 220 and the opposite electrode 230. Because the intermediate layer 220 and the opposite electrode 230 are deposited without a separate mask, a deposition material for forming the intermediate layer 220 and a deposition material for forming the opposite electrode 230 may form a dummy intermediate layer and a dummy opposite electrode through the metal bank layer 300. As described above, because the two opposite sides of the metal bank layer 300 include an undercut structure, the dummy intermediate layer may be disconnected (or separated) one more time. For example, the dummy intermediate layer may include a first portion 220b of the dummy intermediate layer and a second portion 220c of the dummy intermediate layer, and the dummy opposite electrode may include a first portion 230b of the dummy opposite electrode and a second portion 230c of the dummy opposite electrode.

As described above, among layers formed on the substrate 100, a layer including an organic material among may serve as a transmission path of foreign substance such as moisture, and foreign substance such as moisture may damage the light-emitting diode. As in the display apparatus of FIG. 7, in the case where the metal bank layer 300 disconnects the intermediate layer 220 and the opposite electrode 230, impurities may be prevented from progressing toward the first to third light-emitting diodes ED1, ED2, and ED3 through the intermediate layer 220 and the like. Particularly, because the two opposite sides of the metal bank layer 300 include the undercut structure, the first portion 220b of the dummy intermediate layer and the second portion 220c of the dummy intermediate layer may be separated from each other around the metal bank layer 300, and thus, the organic material layer such as the intermediate layer 220 may be separated one more time. For example, because a double anchor structure may be formed through the metal bank layer 300, contaminants penetrating the first to third light-emitting diodes ED1, ED2, and ED3 may be reduced. Accordingly, in the display apparatus according to another embodiment, because contaminants such as moisture are prevented from penetrating the light-emitting diode, layer-floating defects of an encapsulation layer 500 and pixel shrinkage defects due to oxidation of the opposite electrode 230 may be reduced. Furthermore, because the second portions 220c of the dummy intermediate layer are apart from each other, and the second portions 230c of the dummy opposite electrode are apart from each other, effects of suppressing defect growth such as black spots progressing through the dummy intermediate layer or the dummy opposite electrode may be simultaneously implemented.

The edge or outer portion (or neighboring portion) of the opposite electrode 230 may extend beyond the edge or outer portion (or neighboring portion) of the intermediate layer 220 and directly contact the lateral surface of the first metal layer 310. Accordingly, because the first metal layer 310 of the metal bank layer 300 is electrically connected to the auxiliary line VSL (see FIG. 2A), the opposite electrode 230 may be electrically connected to the auxiliary line VSL. For example, because the first metal layer 310 is connected to the auxiliary line VSL and may have the same voltage level as a voltage of the auxiliary line VSL, the opposite electrode 230 connected to the first metal layer 310 may be configured to receive the common voltage ELVSS. In addition, because the metal bank layers 300 surrounding respective sub-pixels have portions connected to each other, the metal bank layers 300 may have the same voltage level. Accordingly, the first opposite electrode 1230, the second opposite electrode 2230, and the third opposite electrode 3230 each connected to the first metal layer 310 of the metal bank layer 300 may be configured to receive the same voltage level as a voltage (e.g., the common voltage) provided by the auxiliary line VSL.

In the display apparatus according to an embodiment, resolution may be improved by patterning the intermediate layer and the opposite electrode using the structure. Furthermore, because the double anchor structure is formed using the structure, a layer-floating defect and a moisture transmission defect may be prevented. However, this effect is an example, and the scope of the disclosure is not limited by this effect.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the disclosure.

What is claimed is:

1. A display apparatus, comprising:
a first sub-pixel electrode;
a first structure including a first opening and surrounding the first sub-pixel electrode in a plan view, the first opening overlapping the first sub-pixel electrode;
an inorganic bank layer disposed on the first sub-pixel electrode and under the first structure;
a first intermediate layer disposed on an inner surface of the first structure facing the first opening, the first intermediate layer overlapping the first sub-pixel electrode;
a first opposite electrode disposed on an inner surface of the first structure facing the first opening, the first opposite electrode overlapping the first intermediate layer;
a first portion of a first dummy intermediate layer disposed on the first structure; and
a second portion of the first dummy intermediate layer disposed on an outer surface which is opposite to the inner surface of the first structure, wherein
the first intermediate layer, the first portion of the first dummy intermediate layer, and the second portion of the first dummy intermediate layer are apart from each other, and
the first intermediate layer, the first portion of the first dummy intermediate layer, and the second portion of the first dummy intermediate layer include a same material.

2. The display apparatus of claim 1, further comprising:
a substrate;
a thin-film transistor disposed on the substrate; and
an organic insulating layer disposed on the thin-film transistor,
wherein the second portion of the first dummy intermediate layer is disposed on the organic insulating layer.

3. The display apparatus of claim 1, further comprising:
a first portion of a first dummy opposite electrode disposed on the first portion of the first dummy intermediate layer; and
a second portion of the first dummy opposite electrode disposed on the second portion of the first dummy intermediate layer, wherein
the first opposite electrode, the first portion of the first dummy opposite electrode, and the second portion of the first dummy opposite electrode are apart from each other, and
the first opposite electrode, the first portion of the first dummy opposite electrode, and the second portion of the first dummy opposite electrode include a same material.

4. The display apparatus of claim 1, further comprising:
a second sub-pixel electrode;
a second structure including a second opening and surrounding the second sub-pixel electrode, the second opening overlapping the second sub-pixel electrode;
a second intermediate layer disposed on an inner surface of the second structure facing the second opening, the second intermediate layer overlapping the second sub-pixel electrode;
a second opposite electrode disposed on an inner surface of the second structure facing the second opening, the second opposite electrode overlapping the second intermediate layer;
a first portion of a second dummy intermediate layer disposed on the second structure; and
a second portion of the second dummy intermediate layer disposed on an outer surface which is opposite to the inner surface of the second structure, wherein
the second intermediate layer, the first portion of the second dummy intermediate layer, and the second portion of the second dummy intermediate layer are apart from each other, and
the second intermediate layer, the first portion of the second dummy intermediate layer, and the second portion of the second dummy intermediate layer include a same material.

5. The display apparatus of claim 4, wherein the first structure and the second structure are apart from each other.

6. The display apparatus of claim 5, wherein the second portion of the first dummy intermediate layer and the second portion of the second dummy intermediate layer are disposed between the first structure and the second structure.

7. The display apparatus of claim 4, further comprising:
a first sub-pixel inorganic encapsulation layer disposed on the first opposite electrode; and
a second sub-pixel inorganic encapsulation layer disposed on the second opposite electrode, wherein
the first sub-pixel inorganic encapsulation layer extends to overlap an upper surface and a lateral surface of the first structure, and an upper surface of the first opposite electrode, and
the second sub-pixel inorganic encapsulation layer extends to overlap an upper surface and a lateral surface of the second structure, and an upper surface of the second opposite electrode.

8. The display apparatus of claim 7, wherein the first sub-pixel inorganic encapsulation layer and the second sub-pixel inorganic encapsulation layer are apart from each other.

9. The display apparatus of claim 1, wherein
the first structure includes a separator, and
two opposite sides of the separator are each a reverse-tapered sloped surface.

10. The display apparatus of claim 9, further comprising:
an auxiliary electrode disposed between the inorganic bank layer and the first structure,
wherein the first opposite electrode is in direct contact with the auxiliary electrode.

11. The display apparatus of claim 9, wherein a width of the separator is less than or equal to a width of the inorganic bank layer disposed under the separator.

12. The display apparatus of claim 9, wherein a height of the separator is about 2 μm to about 4 μm.

13. The display apparatus of claim 9, wherein the separator includes at least one of an organic insulating material and a photosensitive material.

14. The display apparatus of claim 1, wherein
the first structure includes a metal bank layer, and
the metal bank layer includes a first metal layer and a second metal layer on the first metal layer.

15. A method of manufacturing a display apparatus, the method comprising:
forming a first sub-pixel electrode;
forming an inorganic bank layer overlapping an end of the first sub-pixel electrode;
forming a first structure disposed on the inorganic bank layer, including a first opening, and surrounding the first sub-pixel electrode in a plan view, the first opening overlapping the first sub-pixel electrode;
forming a first intermediate layer disposed on an inner surface of the first structure facing the first opening, the first intermediate layer overlapping the first sub-pixel electrode;
forming a first opposite electrode disposed on the inner surface of the first structure facing the first opening, the first opposite electrode overlapping the first intermediate layer;
forming a first portion of a first dummy intermediate layer disposed on the first structure; and
forming a second portion of the first dummy intermediate layer disposed on an outer surface which is opposite to the inner surface of the first structure, wherein
the first intermediate layer and the first portion of the first dummy intermediate layer are disconnected by the inner surface of the first structure, and
the first portion of the first dummy intermediate layer and the second portion of the first dummy intermediate layer are disconnected by the outer surface of the first structure.

16. The method of claim 15, further comprising:
forming a first portion of a first dummy opposite electrode disposed on the first portion of the first dummy intermediate layer;
forming a second portion of the first dummy opposite electrode disposed on the second portion of the first dummy intermediate layer; and
forming a first sub-pixel inorganic encapsulation layer disposed on the first opposite electrode, wherein
the first opposite electrode and the first portion of the first dummy opposite electrode are disconnected by the inner surface of the first structure,
the first portion of the first dummy opposite electrode and the second portion of the first dummy opposite electrode are disconnected by the outer surface of the first structure, and
the first sub-pixel inorganic encapsulation layer extends to overlap an upper surface and a lateral surface of the first structure and an upper surface of the first opposite electrode.

17. The method of claim 15, further comprising:
forming a second sub-pixel electrode;
forming a second structure including a second opening overlapping the second sub-pixel electrode, the second structure surrounding the second sub-pixel electrode in a plan view;
forming a second intermediate layer disposed on an inner surface of the second structure facing the second opening, the second intermediate layer overlapping the second sub-pixel electrode;
forming a second opposite electrode disposed on the inner surface of the second structure facing the second opening, the second opposite electrode overlapping the second intermediate layer;
forming a first portion of a second dummy intermediate layer disposed on the second structure; and
forming a second portion of the second dummy intermediate layer disposed on an outer surface which is opposite to the inner surface of the second structure, wherein
the second intermediate layer and the first portion of the second dummy intermediate layer are disconnected by the inner surface of the second structure, and
the first portion of the second dummy intermediate layer and the second portion of the second dummy intermediate layer are disconnected by the outer surface of the second structure.

18. The method of claim 17, wherein the first structure and the second structure are apart from each other.

19. The method of claim 15, wherein
the forming of the first structure includes forming a separator having two opposite sides each having a form of a reverse-tapered sloped surface, and
the forming of the separator includes exposing and developing a photosensitive material of the separator.

20. The method of claim 15, wherein
the forming of the first structure includes forming a metal bank layer, and
the metal bank layer includes a first metal layer and a second metal layer on the first metal layer.
